(19) United States
(12) Patent Application Publication
(10) Pub. No.: US 2025/0393361 A1
(43) Pub. Date: Dec. 25, 2025

(54) DISPLAY DEVICE, METHOD FOR MANUFACTURING THE SAME, AND ELECTRONIC DEVICE INCLUDING THE DISPLAY DEVICE

(71) Applicant: Samsung Display Co., LTD., Yongin-si (KR)

(72) Inventors: Jung An LEE, Yongin-si (KR); Sun PARK, Yongin-si (KR); Bo Bae LEE, Yongin-si (KR); Yu Jin LEE, Yongin-si (KR)

(21) Appl. No.: 19/020,792

(22) Filed: Jan. 14, 2025

(30) Foreign Application Priority Data
Jun. 21, 2024 (KR) 10-2024-0080774

(51) Int. Cl. H10H 29/49; H10H 29/01; H10H 29/39

(52) U.S. Cl. CPC H10H 29/49; H10H 29/012; H10H 29/032; H10H 29/39

(57) ABSTRACT

A display device and a manufacturing method thereof are provided. A display device includes a substrate, a pixel electrode and a common electrode spaced from each other on the substrate, a first reflective electrode on the pixel electrode and a second reflective electrode on the common electrode, respectively, a first bottom sacrificial electrode on the first reflective electrode and a second bottom sacrificial electrode on the second reflective electrode, an organic layer covering at least a portion of the first and second sacrificial electrodes, a light emitting element on the organic layer and including a semiconductor stack, a first contact electrode, and a second contact electrode, a first connection electrode connecting the pixel electrode and the first contact electrode and a second connection electrode connecting the common electrode and the second contact electrode and a first upper sacrificial electrode between the first contact electrode and the organic layer.

### CROSS-REFERENCE TO RELATED APPLICATION

The present application claims priority to and the benefit of Korean Patent Application No. 10-2024-0080774, filed on Jun. 21, 2024, in the Korean Intellectual Property Office, the entire disclosure of which is incorporated by reference herein.

### BACKGROUND

### 1. Field

The present disclosure relates to a display device and a method for manufacturing the same.

### 2. Description of the Related Art

As the information society develops, the demand for display devices for displaying images is increasing in various forms. The display device may be a flat panel display device such as a liquid crystal display, a field emission display, or a light emitting display, and/or the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has less deterioration issues and a longer lifespan compared to organic light emitting diode (OLED) elements.

### SUMMARY

Aspects and features of embodiments of the present disclosure are to provide a display device, a method for manufacturing the same, and an electronic device including the display device that may reduce the contact resistance caused by contaminant particles that may be generated during the heat pressing process of a light emitting element and to reduce the possibility of causing dark spots when the display panel is turned on.

However, aspects of the present disclosure are not restricted to the one set forth herein. The above and other aspects of the present disclosure will become more apparent to one of ordinary skill in the art to which the present disclosure pertains by referencing the detailed description of the present disclosure given below. According to one or more embodiments of the present disclosure, a display

device includes a substrate, a pixel electrode and a common electrode spaced from each other on the substrate, a first reflective electrode on the pixel electrode and a second reflective electrode on the common electrode, respectively, a first bottom sacrificial electrode on the first reflective electrode and a second bottom sacrificial electrode on the second reflective electrode, an organic layer covering at least a portion of the first and second sacrificial electrodes, a light emitting element on the organic layer and including a semiconductor stack, a first contact electrode, and a second contact electrode, a first connection electrode connecting the pixel electrode and the first contact electrode and a second connection electrode connecting the common electrode and the second contact electrode and a first upper sacrificial electrode between the first contact electrode and the organic layer, and a second upper sacrificial electrode between the second contact electrode and the organic layer.

The first contact electrode and the second contact electrode are on a bottom surface and a side surface of the semiconductor stack, respectively, and are spaced from a top surface of the semiconductor stack by a first separation distance.

The first upper sacrificial electrode and the second upper sacrificial electrode are on a bottom surface and a side surface of the semiconductor stack, respectively, and are spaced from the top surface of the semiconductor stack by a second separation distance, wherein the second separation distance is greater than the first separation distance.

The first contact electrode is in direct contact with the first connection electrode on a side of the semiconductor stack, and the second contact electrode is in direct contact with the second connection electrode on a side of the semiconductor stack.

The light emitting element completely overlaps the first upper sacrificial electrode and the second upper sacrificial electrode.

The light emitting element completely overlaps the first upper sacrificial electrode and the second upper sacrificial electrode.

The first bottom sacrificial electrode exposes at least a portion of the first reflective electrode, and the second bottom sacrificial electrode exposes at least a portion of the second reflective electrode.

The first connection electrode is in direct contact with the exposed pixel electrode, and the second connection electrode in direct contact with the exposed common electrode.

The first connection electrode is in direct contact with the exposed pixel electrode, and the second connection electrode is in direct contact with the exposed common electrode.

The light emitting element further includes a conductive layer between the organic layer and the semiconductor stack and a protective film on side surfaces of the conductive layer and side surfaces of the semiconductor stack, wherein the first contact electrode is on the protective film and is connected to the conductive layer that is exposed without being covered by the protective film, wherein the second contact electrode is on the protective film and is in a hole penetrating the conductive layer and a portion of the semiconductor stack.

The organic layer covers the entire surface of the first bottom sacrificial electrode and the second bottom sacrificial electrode, the organic layer includes a first connection hole penetrating the first bottom sacrificial electrode and a second connection hole penetrating the organic layer and the second bottom sacrificial electrode, wherein the first connection electrode connects the pixel electrode and the first contact electrode through the first connection hole, wherein the second connection electrode connects the common electrode and the second contact electrode through the second connection hole.

The semiconductor stack further includes: a first semiconductor layer on the organic layer and including a semiconductor material layer doped with a first conductive dopant, an active layer on the first semiconductor layer and a second semiconductor layer on the active layer and including a semiconductor material layer doped with a second conductive dopant.

According to an aspect of the present disclosure, a display device includes a substrate, a pixel electrode a pixel electrode PXE on the substrate, a reflective electrode SRF on each of the pixel electrodes, a bottom sacrificial electrode BSC on the reflective electrode, an organic layer 210 on the bottom sacrificial electrode and a light emitting element LE on the organic layer and including a semiconductor stack and a contact electrode, a connection electrode BE connecting the pixel electrode and the contact electrode and an upper sacrificial electrode between the contact electrode and the organic layer.

The contact electrode is on a bottom surface and the side surface of the semiconductor stack, and is spaced from the top surface of the semiconductor stack by a first separation distance, wherein the upper sacrificial electrode is on a bottom surface and a side surface of the semiconductor stack, respectively, and is spaced from the top surface of the semiconductor stack by a second separation distance, wherein the second separation distance is greater than the first separation distance.

The contact electrode is in direct contact with the connection electrode on a side surface of the semiconductor stack.

The bottom sacrificial electrode exposes at least a portion of the reflective electrode, wherein the reflective electrode exposes at least a portion of the pixel electrode.

The connection electrode directly contacts the exposed pixel electrode.

The light emitting element further includes, a conductive layer between the organic layer and the semiconductor stack and a protective film on side surfaces of the conductive layer and side surfaces of the semiconductor stack, wherein the contact electrode is on the protective film and is connected to the conductive layer exposed without being covered by the protective film, where a connection hole penetrating the organic layer and the first bottom sacrificial electrode is included when the organic layer covers the entire surface of the bottom sacrificial electrode, wherein the connection electrode connects the pixel electrode and the contact electrode through the connection hole.

According to one or more embodiments of the present disclosure, a method for manufacturing a display device includes forming an upper sacrificial electrode covering one side and a side surface of a light emitting element, and disposing the light emitting element on an adhesive layer applied on a first substrate, wherein the light emitting element includes a semiconductor stack, a first contact electrode, and a second contact electrode, forming a second substrate on which a pixel electrode and a common electrode are located, the pixel electrode and common electrode being formed to sequentially stack first and second reflective electrodes and first and second bottom sacrificial electrodes, respectively, forming an organic layer covering at least a portion of the first and second sacrificial electrodes, transferring the light emitting elements onto the organic layer so that the first and second contact electrodes of each of the light emitting elements face the pixel electrodes and the common electrodes, forming a mask covering a portion of the bottom sacrificial electrode and the upper sacrificial electrode and etching the mask to expose at least a portion of the reflective electrode and at least a portion of the first and second contact electrodes, forming a first connection electrode connecting the pixel electrode and the first contact electrode through an exposed first contact electrode and the first reflective electrode, and a second connection electrode connecting the common electrode and the second contact electrode through an exposed second contact electrode and the second reflective electrode.

The in the sequentially stacking the first and second reflective electrodes and the first and second bottom sacrificial electrodes, depositing a reflective material layer on the entire surface of the substrate to cover the pixel electrode and the common electrode, depositing a sacrificial material layer on the entire surface of the substrate to cover all the reflective material layers, partially etching the sacrificial material layer and the reflective material layer to form the first and second reflective electrodes and the first and second bottom sacrificial electrodes using a first chemical solution that reacts with the first and second reflective electrodes.

In the transferring the light emitting elements onto the organic layer so that the first and second contact electrodes of each of the light emitting elements face the pixel electrodes and the common electrodes, disposing the light emitting elements on the organic layer so that the first and second contact electrodes in each of the light emitting elements face common electrodes with the pixel electrodes, and the transferring the light emitting elements onto the organic layer by heat pressing the light emitting elements, wherein residual particles of the adhesive layer remain on the organic layer and on the surfaces of the first and second bottom sacrificial electrodes and on the surfaces of the first and second upper sacrificial electrodes by the heat pressing.

In one or more embodiments, an electronic device includes a display device; and a display device driver configured to drive the display device, the display device including: a substrate; a pixel electrode and a common electrode spaced from each other on the substrate; a first reflective electrode on the pixel electrode and a second reflective electrode on the common electrode, respectively; a first bottom sacrificial electrode on the first reflective electrode and a second bottom sacrificial electrode on the second reflective electrode; an organic layer covering at least a portion of the first and second bottom sacrificial electrodes; a light emitting element on the organic layer and including a semiconductor stack, a first contact electrode and a second contact electrode; a first connection electrode connecting the pixel electrode and the first contact electrode and a second connection electrode connecting the common electrode and the second contact electrode; and a first upper sacrificial electrode between the first contact electrode and the organic layer, and a second upper sacrificial electrode between the second contact electrode and the organic layer.

In one or more embodiments, the electronic device includes mobile phones, smart phones, tablet personal computers, smart watches, watch phones, mobile communication terminals, electronic notebooks, e-books, portable multimedia players (PMP), navigation, ultra mobile PC (UMPC), televisions, laptops, monitors, billboards, and the internet of things (IOT).

The display device and its manufacturing method according to one or more embodiments, may reduce the possibility of causing dark spots and improve the reliability of the panel when the display panel lights up due to contaminant particles that may be generated during the heat pressing process of the light emitting element.

However, the effects, aspects, and features of the present disclosure are not limited to the aforementioned effects, aspects, and features, and various other effects, aspects, and features are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout drawing illustrating pixels of a display area according to one or more embodiments.

FIG. 6 is a cross-sectional view illustrating one example of a cross-section of a display panel corresponding to the line I-I′ in FIG. 5.

FIG. 7 is a cross-sectional view illustrating one example of an area A1 of FIG. 6 in detail.

FIG. 8 is a cross-sectional view illustrating another example of the area A1 of FIG. 6 in detail.

FIG. 9 is a cross-sectional view illustrating another example of the area A1 of FIG. 6 in detail.

FIG. 10 is a cross-sectional view illustrating another example of the area A1 of FIG. 6 in detail.

FIG. 11 is a cross-sectional view illustrating another example of the area A1 of FIG. 6 in detail.

FIG. 12 is a cross-sectional view illustrating another example of a cross-section of the display panel corresponding to the line I-I′ of FIG. 5.

FIG. 13 is a cross-sectional view illustrating one example of an area A2 of FIG. 12 in detail.

FIG. 14 is a detailed cross-sectional view illustrating another example of an area A2 of FIG. 13.

FIG. 15 is a layout drawing illustrating pixels of a display area according to one or more embodiments.

FIG. 16 is a cross-sectional view illustrating one example of a cross-section of the display panel corresponding to the line I1-I1′ in FIG. 15.

FIG. 17 is a cross-sectional view illustrating one example of an area B1 in FIG. 16 in detail.

FIG. 18 is a cross-sectional view illustrating another example of a cross-section of the display panel corresponding to the line I1-I1′ in FIG. 15.

FIG. 19 is a detailed cross-sectional view illustrating another example of an area B2 in FIG. 18.

FIG. 20 is a flowchart illustrating a method of manufacturing a display device according to one or more embodiments.

FIGS. 21-33 are example drawings to illustrate a method of manufacturing a display device according to one or more embodiments.

FIG. 34 is an example drawing illustrating a smart watch including a display device according to one or more embodiments.

FIGS. 35 and 36 are example drawings illustrating a virtual reality device including a display device according to one or more embodiments.

FIG. 37 is an example drawing illustrating a virtual reality device including a display device according to one or more embodiments.

FIG. 38 is an example drawing illustrating a vehicle instrument panel and center fascia including display devices according to one or more embodiments.

FIG. 39 is an example drawing illustrating a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed

from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object.

In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

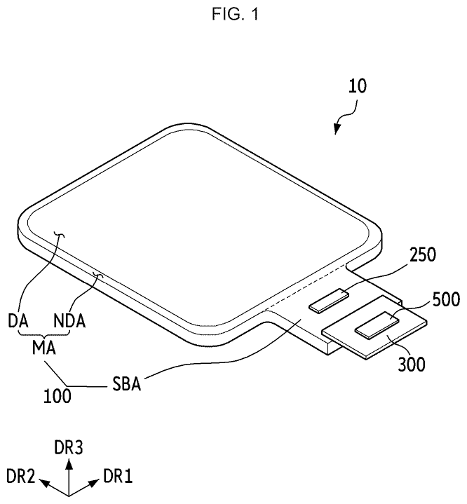

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit board 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

The substrate SUB of the display panel 100 may include a main area MA and a sub area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. When the sub-area SBA is bent, it may overlap the main area MA in the third direction DR3, which is the thickness direction of the display panel 100 (e.g., a third direction DR3). The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. In one or more embodiments, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip on film (COF).

The power supply circuit 500 may generate a plurality of panel driving voltages according to an external power supply voltage. The power supply circuit 500 may be formed as an integrated circuit (IC) and attached to the circuit board 300 using a COF method.

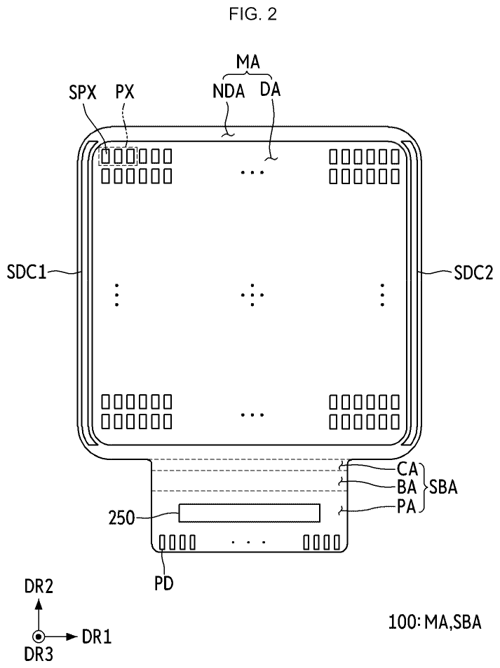

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (to surround) the display area DA along an edge or a periphery of the display area DA. The non-display area NDA may be an edge area of the display panel 100.

A first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100. However, the present disclosure is not limited thereto.

Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

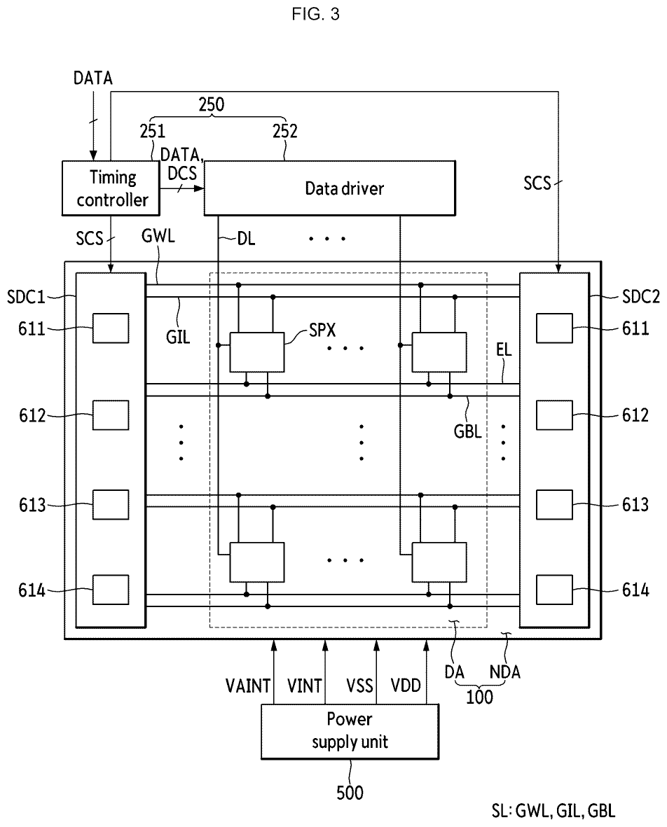

FIG. 3 is a block drawing illustrating a display device according to one or more embodiments.

Referring to FIG. 3, the display area DA includes a plurality of pixels PX and each of the plurality of pixels PX may include a plurality of sub-pixels SPX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and be disposed along the first direction DR1. The plurality of scan lines SL may include a plurality of write scan lines GWL, a plurality of initialization scan lines GIL, and a plurality of bias scan lines GBL. In one or more other embodiments, the plurality of scan lines SL may include a plurality of control scan lines.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. In one or more embodiments, each of the plurality of sub-pixels SPX may be connected to a control scan line from among the plurality of control scan lines. Each of the plurality of sub-pixels SPX may be supplied with a data voltage of the data line DL according to the write scan signal of the write scan line GWL and may emit light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emitting signal output portion 614. Each of the write scan signal output portion 611, the initialization scan signal output portion 612, the bias scan signal output portion 613, and the light emitting signal output portion 614 may receive a scan timing control signal SCS from the timing control circuit (or a timing controller) 251. The write scan signal output portion 611 may generate write scan signals according to the scan timing control signal SCS of the timing control circuit (or the timing controller) 251 and sequentially output them to the write scan lines GWL. A control scan signal output portion may generate control scan signals according to the scan timing control signal SCS and sequentially output them to control scan lines. The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines GBL. The light emitting signal output portion 615 may generate light emitting control signals according to the scan timing control signal SCS and sequentially output them to the emission control lines EL.

The display driving circuit 250 includes the timing control circuit (or the timing controller) 251 and a data driving circuit 252.

The data driving circuit 252 may receive digital video data DATA and a data timing control signal DCS from the timing control circuit (or the timing controller) 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit (or the timing controller) 251 may receive digital video data and timing signals from an external source. The timing control circuit 251 may generate the scan timing control signal SCS and the data timing control signal DCS to control the display panel 100 according to timing signals. The timing control circuit (or the timing controller) 251 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT, and a fourth driving voltage VAINT to the display panel 100.

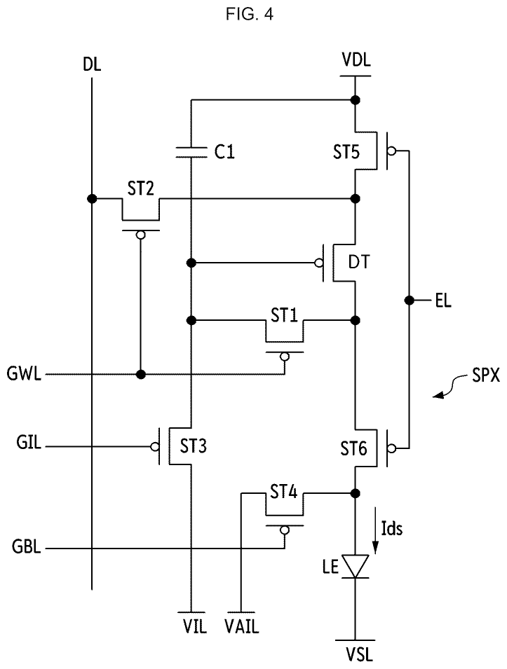

FIG. 4 is an equivalent circuit drawing illustrating a sub-pixel according to one or more embodiments.

Referring to FIG. 4, the sub-pixel SPX according to one or more embodiments may be connected to scan lines GWL, GIL, and GBL, an emission line EL, and a data line DL. For example, the sub-pixel SPX may be connected to the write scan line GWL, the initialization scan line GIL, the bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit PXC.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power voltage VSS is applied.

The capacitor C1 is formed between the gate electrode of the driving transistor DT and the first power supply line VDL to which the first power supply VDD voltage is applied. The first power supply voltage VDD may be at a higher level than the second power supply voltage VSS. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal and an emission signal with a gate low voltage are applied to the initialization scan line GIL, the write scan line GWL, the bias scan line GBL, and the emission line EL, respectively. One electrode of the third transistor ST3 and one electrode of the fourth transistor ST4 may be connected to the initialization voltage line VIL and VAIL respectively.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. The active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor.

In this case, because the first transistor ST1 and the third transistor ST3 are formed as n-type MOSFET, the first transistor ST1 may be turned on when a write scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission signal of the gate low voltage are applied.

Alternatively, the fourth transistor ST4 may be formed of an n-type MOSFET, so that each active layer of the fourth transistor ST4 may be formed of an oxide semiconductor. When the fourth transistor ST4 is formed of an n-type MOSFET, it may be turned on when a scan signal of the gate high voltage is applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

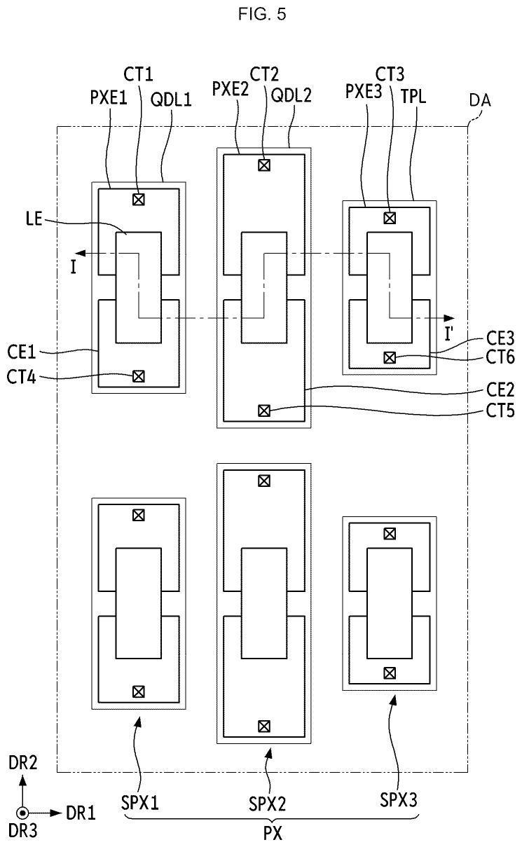

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the sub-pixels may include the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, the plurality of light emitting elements LE, and the second light conversion layer QDL2. The third sub-pixel SPX3 includes a third pixel electrode PXE3, a third common electrode CE3, a plurality of light emitting elements LE, and a light transmission layer TPL.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. Each of the pixel electrodes PXE1, PXE2, and PXE3 and the common electrodes CE1, CE2, and CE3 may have a rectangular planar shape, but the present disclosure is not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits light of the light emitting element LE as it is, the first light conversion layer QDL1 need to convert the light. Therefore, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrodes CE1, CE2, and CE3. Each of the plurality of light emitting elements LE may have a rectangular planar shape, but the present disclosure is not limited thereto. For example, each of the plurality of light emitting elements LE may have a circular planar shape.

The first light conversion layer QDL1 may completely overlap the plurality of light emitting elements LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third sub-pixel SPX3. The light transmission layer TPL may transmit incident light as it is. For example, the light transmission layer TPL may directly transmit the third light emitted from the plurality of light emitting elements LE of the third sub-pixel SPX3.

When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

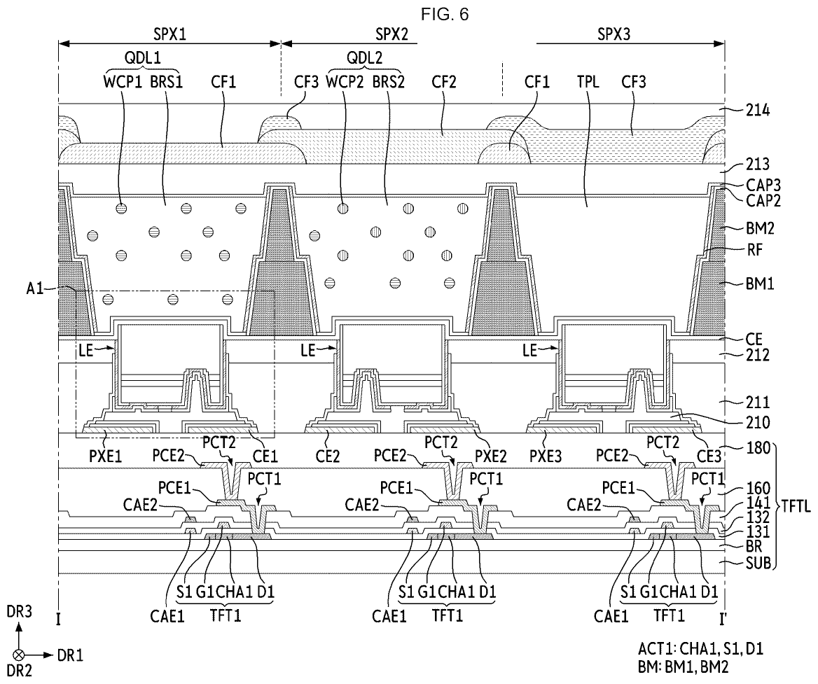

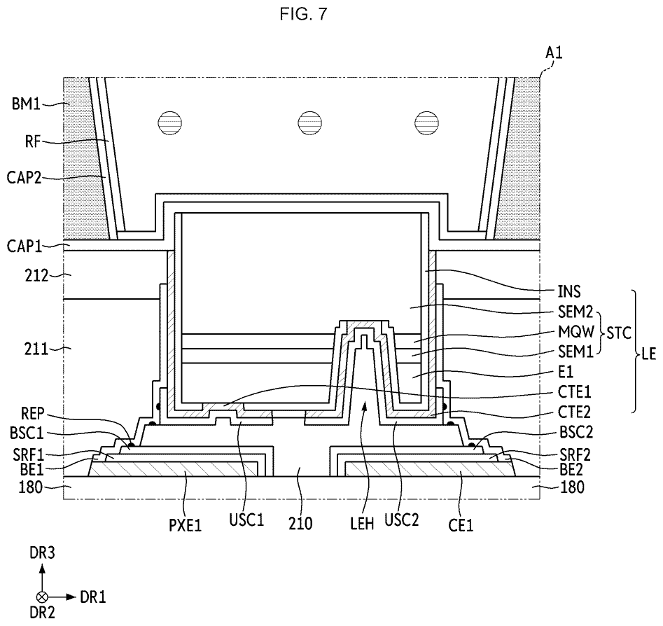

FIG. 6 is a cross-sectional view illustrating one example of a cross-section of a display panel corresponding to the line I-I′ in FIG. 5. FIG. 7 is a cross-sectional view illustrating one example of an area A1 of FIG. 6 in detail.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL and the light emitting layer MQW of the light emitting element layer from moisture penetrating through the substrate SUB, which is vulnerable to moisture penetration. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and on the barrier film BR.

A first gate metal layer may be disposed on the first gate insulating film 131. The first gate metal layer may include the first gate electrode G1 of the thin film transistor TFT1 and the first capacitor electrode CAE1. The first gate electrode G1 may overlap the first active layer ACT1 in the third direction DR3. In FIG. 6, the first gate electrode G1 and the first capacitor electrode CAE1 are shown to be spaced (e.g., disposed apart) from each other, but the first gate electrode G1 and the first capacitor electrode CAE1 may be connected to each other.

A second gate insulating film 132 may be disposed on the first gate electrode G1 of the thin film transistor TFT1, the first capacitor electrode CAE1, and the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 and the first interlayer insulating film 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be disposed on the second source connection electrode PCE2 and the first planarization organic film 160.

The barrier film BR, the first gate insulating film 131, the second gate insulating film 132, and the interlayer insulating film 141 may be formed from an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be disposed on the second planarization organic film 180. The light emitting element layer may include pixel electrodes PXE1, PXE2, PXE3, light emitting elements LE, common electrodes CE1, CE2, CE3, and organic layer 210.

A pixel electrode layer including the pixel electrodes PXE1, PXE2, and PXE3 and the common electrodes CE1, CE2, and CE3 may be disposed on the second planarization organic film 180.

Each of the first pixel electrode PXE1, the second pixel electrode PXE2, and the third pixel electrode PXE3 may be connected to the second source connection electrode PCE2 through a connection hole (CT1, CT2, and CT3 in FIG. 5) penetrating the second planarized organic film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through the common connection hole (CT4, CT5, and CT6 in FIG. 5). The first common electrode CE1 may be connected to the second power supply line (VSL in FIG. 4) through the first common connection hole CT4. The second common electrode CE2 may be connected to the second power supply line (VSL in FIG. 4) through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

An organic layer 210 may be disposed on each pixel electrode layer. For example, the organic layer 210 may cover at least a portion of the pixel electrodes PXE1, PXE2, and PXE3 and at least a portion of the common electrodes CE1, CE2, and CE3.

The organic layer 210 serves to temporarily fix or adhere the upper member (e.g., light emitting element LE). For example, the organic layer 210 may be a film for temporarily adhering an upper member (e.g., light emitting element LE) to each of the pixel electrodes PXE1, PXE2, and PXE3 and the common electrodes CE1, CE2, and CE3. To facilitate temporary adhesion, the thickness of the organic layer 210 may be greater than the thickness of each of the pixel electrodes PXE1, PXE2, and PXE3 and the common electrodes CE1, CE2, and CE3 and greater than the thickness of the contact electrode CTE. The thickness of the organic layer 210 may be about 2 um but is not limited thereto.

The organic layer 210 may be a photosensitive organic film, such as photoresist. Alternatively, the organic layer 210 may be formed from an acrylic resin, an epoxy resin, a phenolic resin, a polyamide resin, a polyimide resin, and/or the like.

A plurality of light emitting elements LE may be disposed on the organic layer 210. FIGS. 6 and 7 illustrate that the light emitting element LE is a flip-type micro LED. The flip-type micro LED refers to an LED in which contact electrodes CTE1 and CTE2 are formed on one side (e.g., the bottom side) of the light emitting element LE.

The light emitting element LE may include a substantially vertical side surface as shown in FIG. 7. For example, the light emitting element LE may be patterned through vertical etching and may have a rectangular or square cross-sectional shape where the width of the top surface and the width of the bottom surface are substantially the same. The height of the light emitting element LE may be about 5.5 μm but is not limited thereto.

Each of the plurality of light emitting elements LE may be formed of an inorganic material such as gallium nitride (GaN).

Each of the plurality of light emitting elements LE may be formed by growing on a semiconductor substrate such as a silicon substrate and/or sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 through an electrostatic method using an electrostatic head or a stamp method using an elastic polymeric material such as PDMS (polydimethylsiloane) or silicone as a transfer substrate.

As shown in FIG. 7, reflective electrodes SRF1 and SRF2 may be disposed on the top surfaces of the pixel electrode PXE1 and the common electrode CE1, respectively.

The reflective electrodes SRF1 and SRF2 may reflect light traveling downward from the light emitting element LE and emit light onto the upper surface of the light emitting element LE. Therefore, because light loss from the light emitting element LE may be reduced, the light efficiency of the light emitting element LE may be increased.

The reflective electrodes SRF1 and SRF2 may expose at least a portion of each of the pixel electrode PXE1 and the common electrode CE1 disposed below. The exposed pixel electrode PXE1 and the common electrode CE1 may be in direct contact with the connection electrodes BE1 and BE2, which will be described later.

The reflective electrodes SRF1 and SRF2 may be formed as a single layer of a highly reflective metal, or may be formed as a multilayer, such as titanium (Ti)/aluminum (Al)/titanium (Ti) or ITO/aluminum (Al)/ITO.

Sacrificial electrodes BSC1 and BSC2 may be disposed on the reflective electrodes SRF1 and SRF2. The sacrificial electrodes BSC1 and BSC2 may be formed of a conductive metal.

The sacrificial electrodes BSC1 and BSC2 may expose at least a portion of the reflective electrodes SRF1 and SRF2. Contamination particles REP may be disposed on the sacrificial electrodes BSC1 and BSC2, but the contamination particles (REP, see FIG. 7) may not be disposed on the reflective electrodes SRF1 and SRF2.

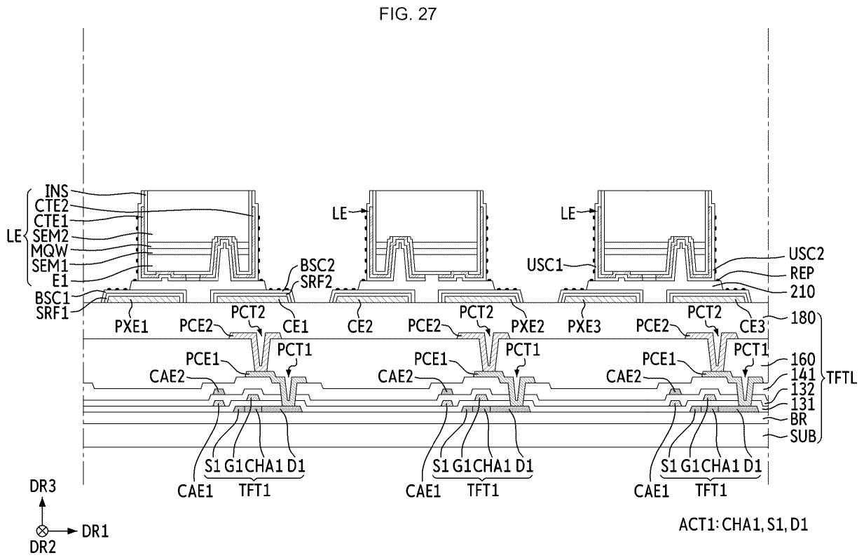

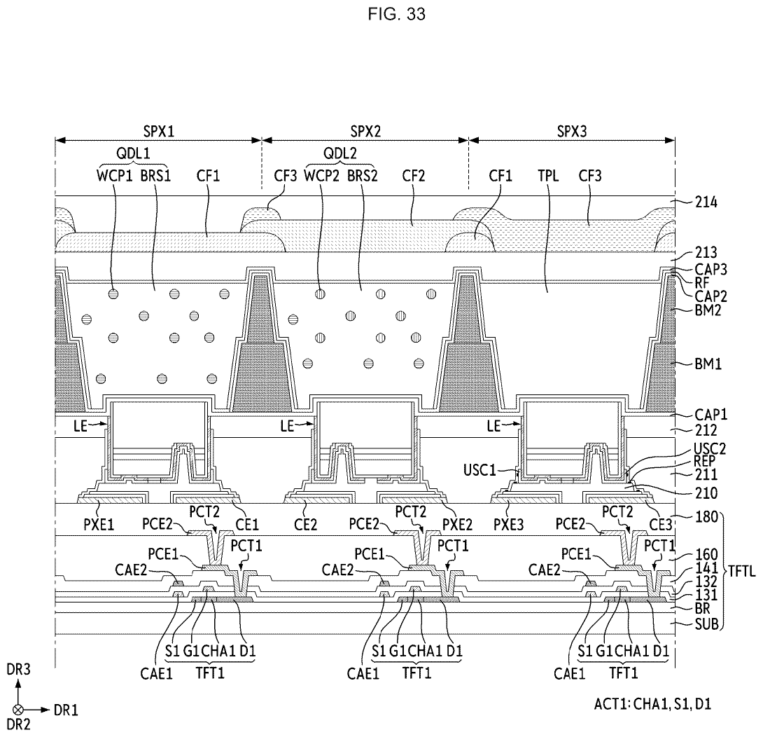

The contamination particles REP will be explained in the process method described with reference to FIGS. 27 and 33 described later.

In one or more embodiments, the reflective electrodes SRF1 and SRF2 may be formed from a multilayer of ITO/Aluminum (Al)/ITO, and the sacrificial electrodes BSC1, BSC2 may be formed from IZO. The ITO/Aluminum (Al)/ITO of the reflective electrodes SRF1 and SRF2 may have a thickness of about 50 Å/850 Å/115 Å, respectively, but is not limited thereto. The sacrificial electrodes BSC1 and BSC2 may be about 100 Å but are not limited thereto. However, thicker sacrificial electrodes BSC1 and BSC2 may increase the probability of cracking of the connection electrodes BE1 and BE2 at the interface of the organic layer 210 and the sacrificial electrodes BSC1 and BSC2.

The light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, and a second semiconductor layer SEM2 sequentially disposed along the third direction DR3.

The conductive layer E1 may be disposed on the lower surface of the first semiconductor layer SEM1. Although FIG. 7 illustrates that the conductive layer E1 covers the entire lower surface of the first semiconductor layer SEM1, the present disclosure is not limited thereto. In one example, the conductive layer E1 may be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may include a semiconductor material layer doped with a first conductive dopant, such as magnesium (Mg), zinc (Zn), calcium (Ca), strontium (Sr), barium (Ba), and/or the like, for example gallium nitride (GaN).

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the first semiconductor layer SEM1. The second semiconductor layer SEM2 may be a semiconductor material layer doped with a second conductivity type dopant such as silicon (Si), germanium (Ge), tin (Sn), etc., for example, gallium nitride (GaN).

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film to protect the bottom and side surfaces of the light emitting element LE. The protective film INS may be disposed on the bottom and side surfaces of the conductive layer E1 and the side surfaces of the semiconductor stack STC. Specifically, the protective film INS may be disposed on the bottom and side surfaces of the conductive layer E1, on the side surface of the first semiconductor layer SEM1, on the side surface of the active layer MQW, and on the side surface of the second semiconductor layer SEM2. The protective film INS may be formed from inorganic films, for example, silicon nitride (SiNₓ), silicon oxide (SiON), silicon oxide (SiOₓ), titanium oxide (TiOₓ), and/or aluminum oxide (AlOₓ). The protective film INS is preferably disposed from one end of the side of the light emitting element LE to the other end but may be disposed partially spaced from one end due to processing errors.

A hole LEH exposing the second semiconductor layer SEM2 may be formed through the conductive layer E1, the first semiconductor layer SEM1, and the active layer MQW of the light emitting element LE. The hole LEH may have a rectangular plan shape, but the present disclosure is not limited thereto. In one example, the hole LEH may have a polygonal plan shape such as a circle, an oval, or a square.

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be disposed on at least one side of the semiconductor stack STC and on at least one side and bottom of the conductive layer E1. The first contact electrode CTE1 may be disposed on the exposed bottom surface of the conductive layer E1 that is not covered by the protective film INS. Therefore, the first contact electrode CTE1 may be electrically connected to the conductive layer E1.

The second contact electrode CTE2 may be disposed on at least one side of the semiconductor stack STC and on at least one side and bottom of the conductive layer E1. In this case, the first contact electrode CTE1 may be disposed on the first side of the semiconductor stack STC and a first side of the conductive layer E1, while the second contact electrode CTE2 may be disposed on a second side of the semiconductor stack STC and a second side of the conductive layer E1.

The second contact electrode CTE2 may be disposed on the protective film INS disposed in the hole LEH and on the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may be disposed on at least a portion of the side surface of the semiconductor stack STC. From among the side surfaces of the semiconductor stack STC, at least an area adjacent to the top surface of the semiconductor stack STC may be exposed without being covered by the first and second contact electrodes CTE1 and CTE2. For example, the first and second contact electrodes CTE1 and CTE2 are spaced (e.g., spaced apart) from the top surface of the semiconductor stack STC in the third direction DR3. The first contact electrode CTE1 and the second contact electrode CTE2 may be formed at least lower than one end of the protective film INS. For example, the separation distance between the first contact electrode CTE1 and the second contact electrode CTE2 and the top surface of the semiconductor stack STC may be greater than the separation distance between the protective film INS and the top surface of the semiconductor stack STC.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed from a two-layer structure of chromium (Cr) and/or gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first and second contact electrodes CTE1 and CTE2 may be disposed on three sides of the semiconductor stack STC. For example, when the semiconductor stack STC includes first to fourth sides, the first contact electrode CTE1 may be disposed on the first side, the second side, and the third side, and the second contact electrode CTE2 may be disposed on the second side, third side, and fourth side.

The sacrificial electrodes USC1 and USC2 are disposed between the contact electrodes CTE1 and CTE2 and the organic layer 210. The sacrificial electrodes USC1 and USC2 may be in direct contact with the organic layer 210. In this specification, the sacrificial electrodes BSC1, BSC2 are referred to as the bottom sacrificial electrodes BSC1, BSC2 and the sacrificial electrodes USC1, USC2 are referred to as the upper sacrificial electrodes to clearly distinguish between the sacrificial electrodes USC1 and USC2 and the sacrificial electrodes BSC1 and BSC2.

The upper sacrificial electrodes USC1 and USC2 may be disposed on the first contact electrode CTE1 and the second contact electrode CTE2 and overlap at least one side and bottom surface of the semiconductor stack STC. For example, the first upper sacrificial electrode USC1 may be disposed on the first contact electrode CTE1 to overlap at least one side of the semiconductor stack STC and the lower surface of the conductive layer E1. Accordingly, the first upper sacrificial electrode USC1 may be electrically connected to the conductive layer E1 through the first contact electrode CTE1.

The second upper sacrificial electrode USC2 may be disposed on the second contact electrode CTE2 to overlap at least one side of the semiconductor stack STC and at least one side and a bottom surface of the conductive layer E1. For example, the first upper sacrificial electrode USC1 is disposed on the first side of the semiconductor stack STC and the first contact electrode CTE1 is disposed on the first side of the conductive layer E1 while the second upper sacrificial electrode USC2 may be disposed on the second contact electrode CTE2 disposed on the second side of the semiconductor stack STC and the second side of the conductive layer E1. Further, the second upper sacrificial electrode USC2 may be electrically connected to the second semiconductor layer SEM2 through the second contact electrode CTE2 in the hole LEH.

The upper sacrificial electrodes USC1 and USC2 may be formed of a metal having the same conductivity as the bottom sacrificial electrodes BSC1 and BSC2. For example, the upper sacrificial electrodes USC1 and USC2 may be formed of IZO.

On the other hand, contaminant particles REP may be disposed on the upper sacrificial electrodes USC1 and USC2 that are disposed on the side of the semiconductor stack STC. In addition, the contaminant particles REP may also be disposed on a side of the organic layer 210 and on an upper surface of the organic layer 210 that does not overlap with the light emitting element LE (when the organic layer 210 protrudes outwardly from the light emitting element LE).

The connection electrodes BE1 and BE2 electrically connect the light emitting element LE and the pixel electrode layer.

In one or more embodiments, the first connection electrode BE1 connects the first contact electrode CTE1 of the light emitting element LE and the pixel electrodes PXE1, PXE2, and PXE3.

The first connection electrode BE1 is disposed on the first contact electrode CTE1 disposed on the side of the semiconductor stack STC and extends along the first upper sacrificial electrode USC1 and the organic layer 210 and may be disposed on a first bottom sacrificial electrode BSC1, a first reflective electrode SRF1 exposed by the first bottom sacrificial electrode BSC1, and the pixel electrodes PXE1, PXE2, and PXE3 exposed by the first reflective electrode SRF1. Accordingly, the first connection electrode BE1 may connect the conductive layer E1 of the light emitting element LE and the pixel electrodes PXE1, PXE2, and PXE3.

The first connection electrode BE1 may include molybdenum (Mo), aluminum (Al), chromium (Cr), gold (Au), titanium (Ti), nickel (Ni), neodymium (Nd), and/or copper (Cu). Alternatively, the first connection electrode BE1 may be made of a transparent conductive material (TCO) such as indium tin oxide (ITO) and indium zinc oxide (IZO).

The second connection electrode BE2 connects the second contact electrode CTE2 of the light emitting element LE and the common electrodes CE1, CE2, and CE3. The second connection electrode BE2 may be disposed on the second contact electrode CTE2 disposed on the side of the semiconductor stack STC, extends along the second upper sacrificial electrode USC2 and the organic layer 210, and may be disposed on a second bottom sacrificial electrode BSC2, a second reflective electrode SRF2 exposed by the second bottom sacrificial electrode BSC2, and a common electrodes CE1, CE2, and CE3 exposed by the second reflective electrode SRF2. Accordingly, the second connection electrode BE2 may connect the second semiconductor layer SEM2 of the light emitting element LE and the common electrodes CE1, CE2, and CE3.

The first connection electrode BE1 and the second connection electrode BE2 may be spaced (e.g., spaced apart) from the top surface of the semiconductor stack STC in the third direction DR3. The first connection electrode BE1 and the second connection electrode BE2 may be formed at least lower than one end of the first contact electrode CTE1 and the second contact electrode CTE2. For example, the separation distance between the first connection electrode BE1 and the top surface of the semiconductor stack STC may be greater than the separation distance between the first contact electrode CTE1 and the top surface of the semiconductor stack STC, and the separation distance between the second connection electrode BE2 and the top surface of the semiconductor stack STC may be greater than the separation distance between the second contact electrode CTE2 and the top surface of the semiconductor stack STC.

The thickness of the first connection electrode BE1 and the second connection electrode BE2 may each be about 1000 Å but is not limited thereto.

The second connection electrode BE2 may include molybdenum (Mo), aluminum (Al), chromium (Cr), gold (Au), titanium (Ti), nickel (Ni), neodymium (Nd), and/or copper (Cu). Alternatively, the second connection electrode BE2 may be made of a transparent conductive material (TCO), such as indium tin oxide (ITO) and/or indium zinc oxide (IZO).

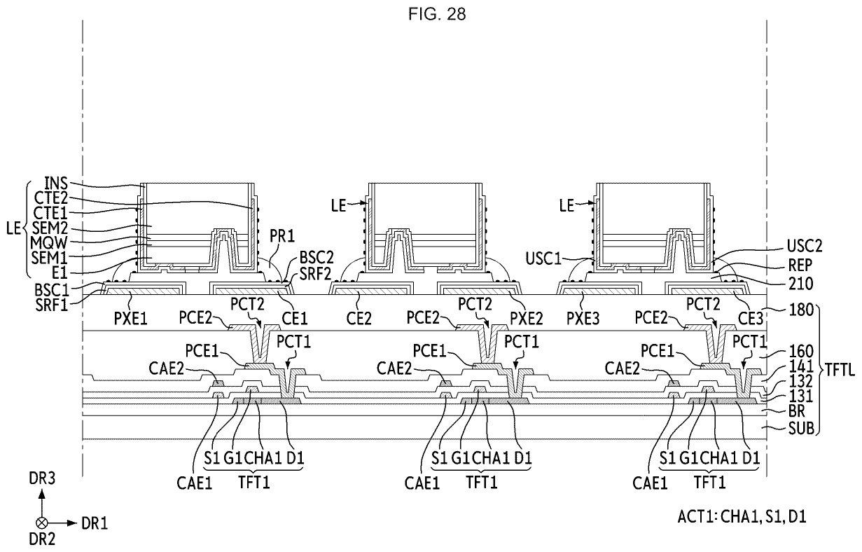

In one or more embodiments, the first connection electrode BE1 and the second connection electrode BE2 may be formed of the same material as the sacrificial electrodes BSC1 and BSC2, for example, indium zinc oxide (IZO). When the first connection electrode BE1 and the second connection electrode BE2 are made of the same material, there is an advantage in terms of process. The advantages of the process will be described in detail with reference to FIG. 28.

The second organic layer 211 may be disposed to cover a portion of the side surfaces of the plurality of light emitting elements LE. Further, the second organic layer 211 may be disposed to cover the first connection electrode BE1 and the second connection electrode BE2.

A third organic film 212 may be disposed on a second organic film 211. The

third organic film 212 may be disposed to cover another portion of the side surface of each of the plurality of light emitting elements LE. The third organic film 212 may be disposed on the protective layer INS, the first connection electrode BE1, and the second connection electrode BE2 that are not covered by the second organic film 211, as shown in FIG. 7. However, the present disclosure is not limited thereto. The top surface of each of the plurality of light emitting elements LE may be exposed without being covered by the third organic film 212.

The second organic film 211 and the third organic film 212 are layers for flattening steps caused by the plurality of light emitting elements LE. When the height of the second organic film 211 is arranged to cover most of the side surfaces of each of the plurality of light emitting elements LE, the third organic film 212 may be omitted.

The second organic film 211 and the third organic film 212 may be formed from an organic film such as an acrylic resin, an epoxy resin, a phenolic resin, a polyamide resin, a polyimide resin, and/or the like.

A first capping layer CAP1 may be disposed on the third organic film 212 and the light emitting element LE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by the compartments of the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE in the third direction DR3.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 or a length of the second direction DR2 may be wider than a length of the second light blocking layer BM2 in the first direction DR1 or a length of the second direction DR2 of the second light-receiving layer BM2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on a second capture layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

Alternatively, the reflective layer RF may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), and/or aluminum oxide (AlOₓ).

The third capping layer CAP3 may be disposed on the second capping layer CAP2, the reflective layer RF, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), and/or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fourth organic film 213 may be disposed on the second capping layer CAP2. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) that has been converted by the first light conversion layer QDL1 from among the third light (e.g., light in the blue wavelength band) emitted from the light emitting element LE and absorb or block the third light (e.g., light in the blue wavelength band) that has not been converted by the first light conversion layer QDL1. Accordingly, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) that has been converted by the second light conversion layer QDL2 from among the third light (e.g., light in the blue wavelength band) emitted from the light emitting element LE and absorb or block the third light (e.g., light in the blue wavelength band) that has not been converted by the second light conversion layer QDL2. Accordingly, the second sub-pixel SPX2 may emit the second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, and/or the like.

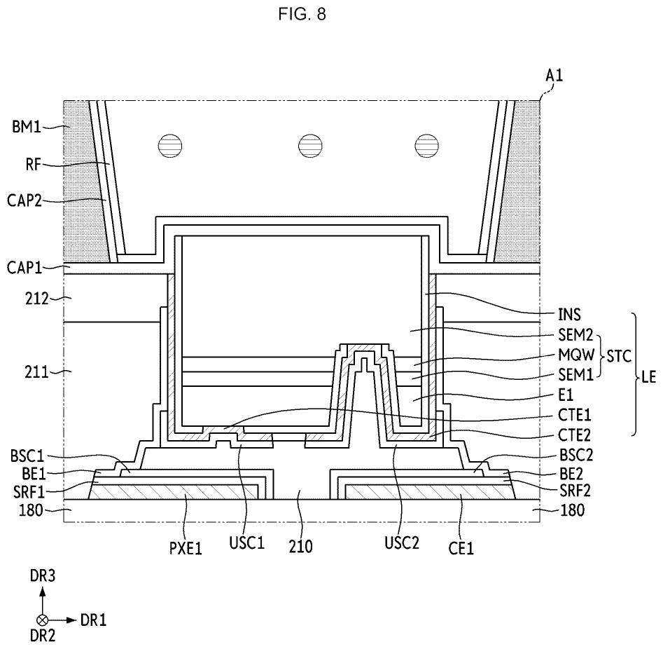

FIG. 8 is a cross-sectional view illustrating another example of the area A1 of FIG. 6 in detail.

The embodiment of FIG. 8 differs from the embodiment of FIG. 7 in that the reflective electrodes SRF1 and SRF2 do not expose the pixel electrodes PXE1, PXE2, and PXE3 and the common electrodes CE1, CE2, and CE3. In FIG. 8, descriptions that overlap with the embodiment described with reference to FIGS. 6 and 7 will not be repeated, and differences from the embodiment of FIG. 7 will be mainly described.

Referring to FIG. 8, the first reflective electrode SRF1 may be disposed to cover all the pixel electrodes PXE1, PXE2, and PXE3, and the second reflective electrode SRF2 may be disposed to cover all the common electrodes CE1, CE2, and CE3.

The first connection electrode BE1 is electrically connected to the pixel electrodes PXE1, PXE2, and PXE3 through the first reflective electrode SRF1 without directly contacting the pixel electrodes PXE1, PXE2, and PXE3. Additionally, the second connection electrode BE2 is electrically connected to the common electrodes CE1, CE2, and CE3 through the second reflective electrode SRF2 without directly contacting the common electrodes CE1, CE2, and CE3.

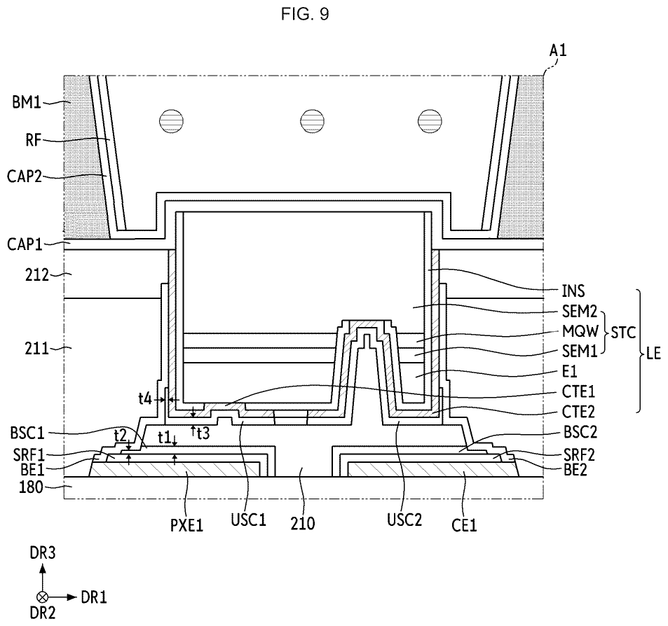

FIG. 9 is a cross-sectional view illustrating another example of the area A1 of FIG. 6 in detail.

The embodiment of FIG. 9 differs from the embodiment of FIG. 7 in that the thickness of the bottom sacrificial electrodes BSC1 and BSC2 and the thickness of the upper sacrificial electrodes USC1 and USC2 are not uniform. In FIG. 9, the description overlapping with the embodiment described with reference to FIGS. 6 and 7 will not be repeated, and the description will be focused on the differences from the embodiment of FIG. 7.

Referring to FIG. 9, the bottom sacrificial electrodes BSC1 and BSC2 has different thicknesses region overlapping with the organic layer 210 and the region not overlapping with the organic layer 210. For example, the thickness t1 of the first bottom sacrificial electrode BSC1 in region overlapping with the organic layer 210 is greater than the thickness t2 of the first bottom sacrificial electrode BSC1 in region not overlapping with the organic layer 210. In addition, the thickness of the second bottom sacrificial electrode BSC2 in region overlapping with the organic layer 210 is greater than the thickness of the second bottom sacrificial electrode BSC2 in region not overlapping with the organic layer 210.

The upper sacrificial electrodes USC1 and USC2 have different thicknesses in the region disposed on the lower surface of the light emitting element LE and in the region disposed on the side surface of the light emitting element LE. For example, the thickness t3 of the upper sacrificial electrodes USC1 and USC2 in the region disposed on the lower surface of the light emitting element LE is thicker than the thickness t4 of the upper sacrificial electrodes USC1 and USC2 in the region disposed on the side surface of the light emitting element LE.

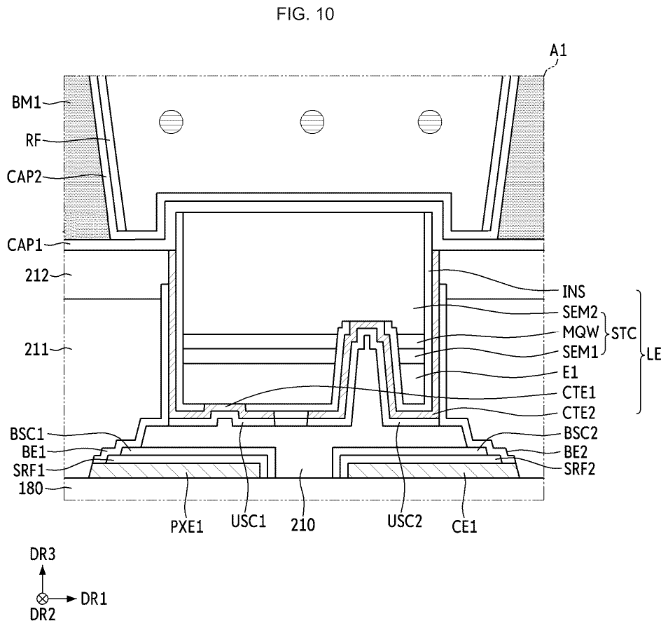

FIG. 10 is a cross-sectional view illustrating another example of the area A1 of FIG. 6 in detail.

The embodiment of FIG. 10 differs from the embodiment of FIG. 7 in that the upper sacrificial electrodes USC1 and USC2 are not disposed on the side of the semiconductor stack STC. In FIG. 10, descriptions that overlap with the embodiments described with reference to FIGS. 6 and 7 will not be repeated, and differences from the embodiment of FIG. 7 will be mainly described.

Referring to FIG. 10, the first upper sacrificial electrode USC1 is disposed between the first contact electrode CTE1 and the organic layer 210 in the third direction DR3 and is not disposed on the side of the semiconductor stack STC and the first conductive layer E1. The second upper sacrificial electrode USC2 is disposed between the second contact electrode CTE2 and the organic layer 210 in the third direction DR3 and is not disposed on the side of the semiconductor stack STC and the first conductive layer E1.

The first connection electrode BE1 is disposed on the first contact electrode CTE1 on the side of the light emitting element LE, and the second connection electrode BE2 is disposed on the second contact electrode CTE2. The first upper sacrificial electrode USC1 is not disposed between the first connection electrode BE1 and the first contact electrode CTE1 on the side of the light emitting element LE. In addition, the second upper sacrificial electrode USC2 is not disposed between the second connection electrode BE2 and the second contact electrode CTE2 on the side of the light emitting element LE.

The light emitting element LE may completely overlap the first upper sacrificial electrode USC1 and the second upper sacrificial electrode USC2.

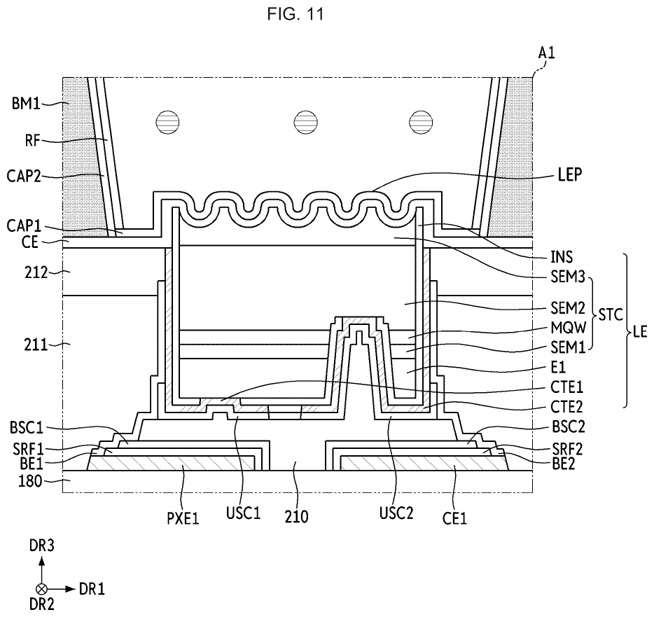

FIG. 11 is a cross-sectional view illustrating another example of the area A1 of FIG. 6 in detail.

The embodiment of FIG. 11 differs from the embodiment of FIG. 7 in that the semiconductor stack STC further includes a third semiconductor layer SEM3. In FIG.

11, descriptions that overlap with the embodiments described with reference to FIGS. 6 and 7 will not be repeated, and differences from the embodiment of FIG. 7 will be mainly described.

The semiconductor stack STC may include a first semiconductor layer SEM1, an active layer MQW, a second semiconductor layer SEM2, and a third semiconductor layer SEM3 sequentially disposed along the third direction DR3.

In the semiconductor stack STC, the third semiconductor layer SEM3 may be disposed on the second semiconductor layer SEM2. The third semiconductor layer SEM3 is a layer of semiconductor material in which the n-type dopant is below a suitable threshold (e.g., a predetermined threshold), which may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the n-type dopant is below a suitable threshold (e.g., a predetermined threshold).

The upper surface of the third semiconductor layer SEM3 may have a light extraction pattern LEP.

The light extraction patterns LEP may be patterns for increasing the efficiency of light emitted from the upper surface of the light emitting element LE. The light extraction patterns LEP may be concave patterns formed in a hemisphere or a semi-ellipse. The light extraction patterns LEP may be concave patterns having a semicircular or semi-elliptical cross-sectional shape.

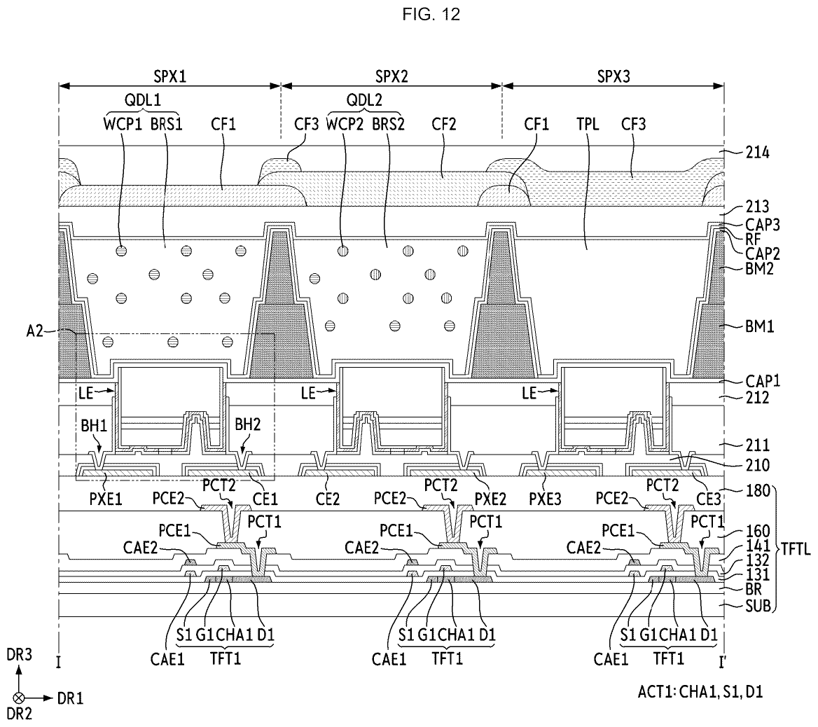

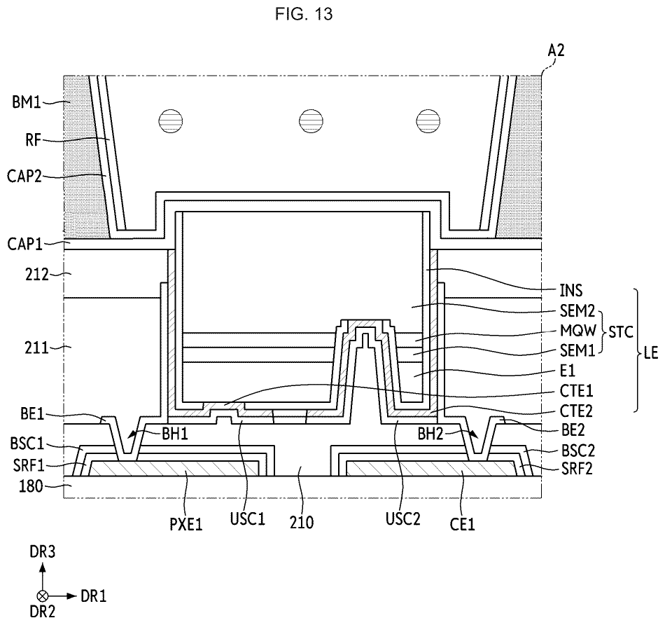

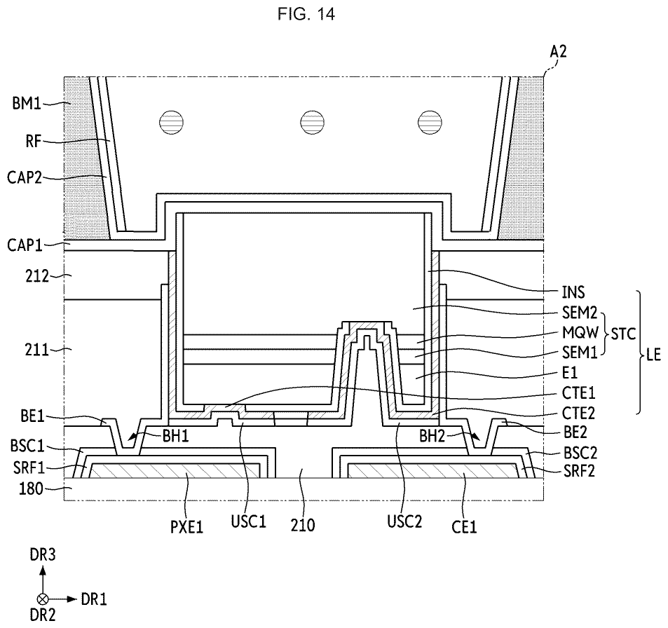

FIG. 12 is a cross-sectional view illustrating another example of a cross-section of the display panel corresponding to the line I-I′ of FIG. 5. FIG. 13 is a cross-sectional view illustrating one example of an area A2 of FIG. 12 in detail. FIG. 14 is a detailed cross-sectional view illustrating another example of the area A2 of FIG. 13.

The embodiments of FIGS. 12-14 differ from the embodiments of FIGS. 6 and 7 in that the organic layer 210 is formed to cover both the pixel electrodes PXE1, PXE2, and PXE3 and the common electrodes CE1, CE2, and CE3 and has a connection hole BH1 and BH2 penetrating the organic layer 210. In the embodiments of FIGS. 12-14, descriptions that overlap with the embodiments of FIGS. 6 and 7 will not be repeated, and differences from the embodiments of FIGS. 6 and 7 will be mainly described.

Referring to FIGS. 12 and 13, the organic layer 210 may be disposed on the entire surface of the pixel electrode layer to cover both the pixel electrodes PXE1, PXE2, and PXE3 and the common electrodes CE1, CE2, and CE3.

The connection holes BH1 and BH2 penetrate the organic layer 210, the bottom sacrificial electrodes BSC1 and BSC2, and the reflective electrodes SRF1 and SRF2 to expose at least a portion of the pixel electrodes PXE1, PXE2, and PXE3 and the common electrodes CE1, CE2, and CE3.

The first connection electrode BE1 connects the first contact electrode CTE1 of the light emitting element LE and the pixel electrodes PXE1, PXE2, and PXE3. The first connection electrode BE1 may be connected to the pixel electrodes PXE1, PXE2, and PXE3 through a first connection hole BH1 that penetrates the organic layer 210, the first bottom sacrificial electrode BSC1, and the first reflective electrode SRF1. For example, the first connection electrode BE1 may contact the pixel electrodes PXE1, PXE2, and PXE3 exposed through the first connection hole BH1.

The second connection electrode BE2 connects the second contact electrode CTE2 of the light emitting element LE and the common electrodes CE1, CE2, and CE3. The second connection electrode BE2 may be connected to the common electrodes CE1, CE2, and CE3 through a second connection hole BH2 that penetrates the organic layer 210, the second bottom sacrificial electrode BSC2, and the second reflective electrode SRF2. For example, the second connection electrode BE2 may contact the common electrodes CE1, CE2, and CE3 exposed through the second connection hole BH2.

As illustrated in FIG. 14, the connection holes BH1 and BH2 penetrate the organic layer 210 and the bottom sacrificial electrodes BSC1 and BSC2 to expose at least a portion of the reflective electrodes SRF1 and SRF2.

The first connection electrode BE1 may be connected to the pixel electrodes PXE1, PXE2, and PXE3 through the first connection hole BH1 penetrating the organic layer 210 and the first bottom sacrificial electrode BSC1. For example, the first connection electrode BE1 may contact the first reflective electrode SRF1 exposed through the first connection hole BH1.

The second connection electrode BE2 may be connected to the common electrodes CE1, CE2, and CE3 through the second connection hole BH2 penetrating the organic layer 210 and the second bottom sacrificial electrode BSC2. For example, the second connection electrode BE2 may contact the second reflective electrode SRF2 exposed through the second connection hole BH2.

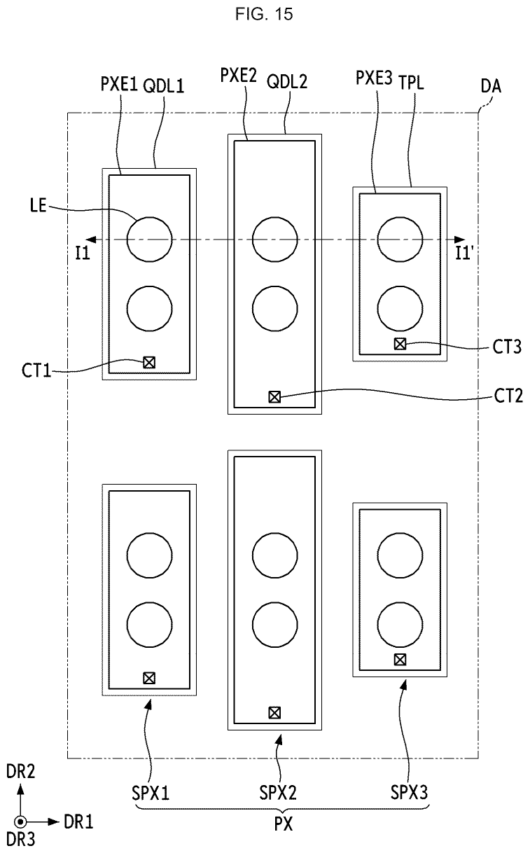

FIG. 15 is a layout drawing illustrating pixels of a display area according to one embodiment.

The embodiment of FIG. 15 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 15, the description overlapping with the embodiment of FIG. 5 is omitted.

Referring to FIG. 15, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape having a short side in the first direction DR1 and a long side in the second direction DR2. An area of the first sub-pixel SPX1, an area of the second sub-pixel SPX2, and an area of the third sub-pixel SPX3 may be set according to the light conversion efficiency of the first light conversion layer QDL1 and the light conversion efficiency of the second light conversion layer QDL2. In one example, the area of the sub-pixel may be larger as the light conversion efficiency is lower.

For example, as shown in FIG. 15, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light emitting element LE, while the first light conversion layer QDL1 must convert the light, the area of the first pixel electrode PXE1 may be larger than the area of the third pixel electrode PXE3.

Each of the pixel electrodes PXE1, PXE2, and PXE3 may be electrically connected to at least one transistor through a pixel connection hole CT1, CT2, and CT3. For example, each of the pixel electrodes PXE1, PXE2, and PXE3 may be electrically connected to the first electrode of the fourth transistor (ST4 of FIG. 4) of the corresponding sub-pixel and the second electrode of the sixth transistor (ST6 of FIG. 4).

A plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be arranged on each of the pixel electrodes PXE1, PXE2, and PXE3.

The first light conversion layer QDL1 may completely overlap the plurality of light emitting elements LE of the first pixel electrode PXE1 and the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the second pixel electrode PXE2 and the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift third light emitted from the plurality of light emitting elements LE of the second sub-pixel SPX2 into second light.

The light transmission layer TPL may completely overlap with the third pixel electrode PXE3 and the plurality of light emitting elements LE of the third sub-pixel SPX3. The light transmission layer TPL may directly transmit the incident light. For example, the light transmission layer TPL may directly transmit third light emitted from the plurality of light emitting elements LE of the third sub-pixel SPX3.

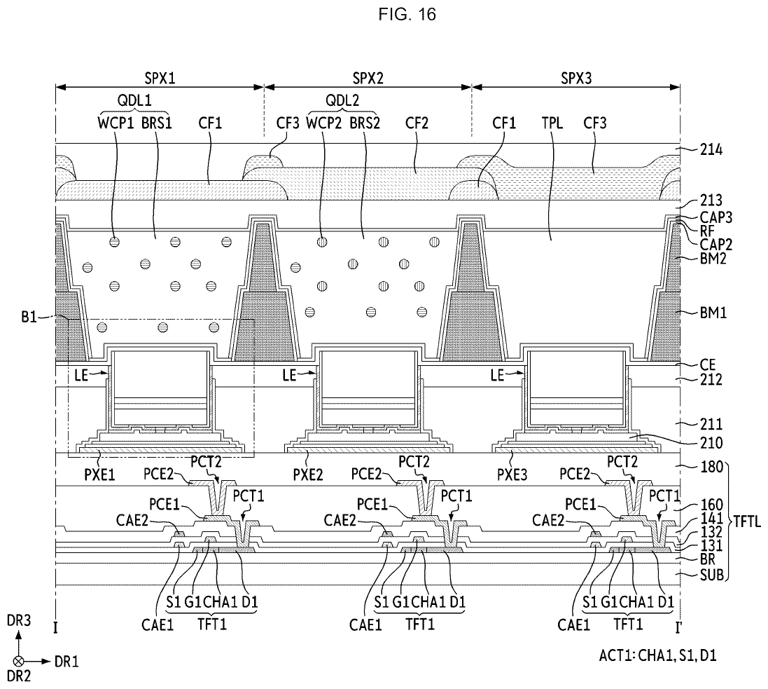

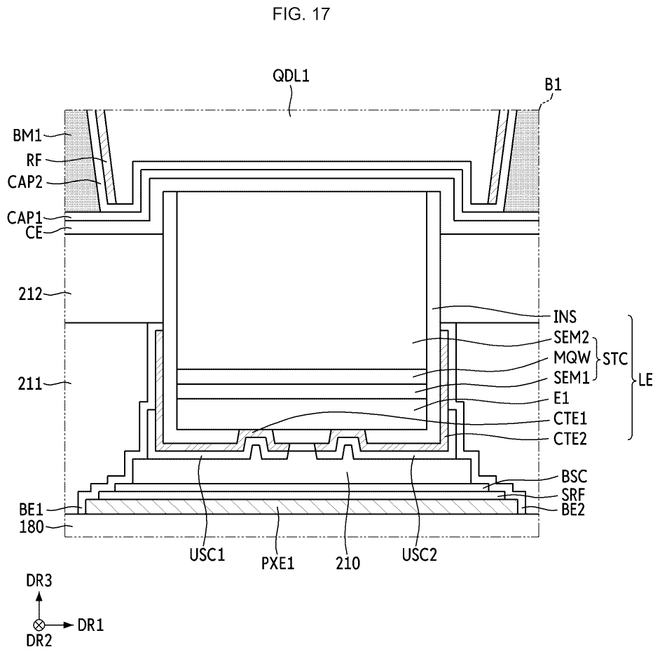

FIG. 16 is a cross-sectional view illustrating one example of a cross-section of the display panel corresponding to the line I1-I1′ in FIG. 15. FIG. 17 is a cross-sectional view illustrating one example of an area B1 in FIG. 16 in detail.

The embodiments of FIGS. 16 and 17 differ from the embodiment of FIG. 6 in that the light emitting elements LE are vertical type micro LED in which each of the plurality of light emitting elements LE extends in a third direction DR3. The vertical type micro LED refers to an LED having a structure in which a first semiconductor layer SEM1, an active layer MQW, and a second semiconductor layer SEM2 are sequentially arranged along the third direction DR3, which is a vertical direction. Each of the plurality of light emitting elements LE may include a substantially vertical side surface. The light emitting elements LE may be patterned through vertical etching and may have a rectangular or square cross-sectional shape in which the width of the upper surface and the width of the lower surface are substantially the same.

In the embodiments of FIGS. 16 and 17, descriptions that overlap with those of the embodiments of FIGS. 6 and 7 will not be repeated.

Referring to FIGS. 16 and 17, a pixel electrode layer may be disposed on the second planarizing organic film 180. The pixel electrode layer may include a first pixel electrode PXE1, a second pixel electrode PXE2, and a third pixel electrode PXE3.

A reflective surface SRF may be disposed on each of the pixel electrodes PXE1, PXE2, and PXE3. The reflective electrode SRF may reflect light traveling downward from the light emitting element LE and emit light to the upper surface of the light emitting element LE. The reflective electrode SRF may be formed as a single layer of a highly reflective metal, or it may be formed as a multilayer, such as titanium (Ti)/aluminum (Al)/titanium (Ti) or ITO/aluminum (Al)/ITO.

The reflective electrode SRF may expose at least a portion of the pixel electrodes PXE1, PXE2, and PXE3 disposed on the bottom. The exposed pixel electrodes PXE1, PXE2, and PXE3 may be in direct contact with a connection electrode BE (BE1, BE2) described below.

A bottom sacrificial electrode BSC may be disposed on the reflective electrode SRF. The bottom sacrificial electrode BSC may be formed of a conductive metal.

The bottom sacrificial electrode BSC may expose at least a portion of the reflective electrode SRF. Contaminant particles REP may be disposed on the bottom sacrificial electrode BSC, but no contaminant particles REP is disposed on the reflective electrode SRF.

In one or more embodiments, the reflective electrode SRF may be formed from a multilayer of ITO/Aluminum (Al)/ITO, and the bottom sacrificial electrode BSC may be formed from IZO.

A plurality of light emitting elements LE may be disposed on the organic layer 210.

Each of the plurality of light emitting elements LE may have a length of several to hundreds of um in the first direction DR1, a length in the second direction DR2, and a length in the third direction DR3. For example, each of the plurality of light emitting elements LE may have a length in the first direction DR1, a length in the second direction DR2, and a length in the third direction DR3 of approximately 100 μm or less.

The light emitting element LE may include a conductive layer E1, a semiconductor stack STC, contact electrodes CTE1 and CTE2, and a protective film INS. The semiconductor stack STC may include a first semiconductor layer SEM1, an active layer MQW, and a second semiconductor layer SEM2 sequentially disposed along the third direction DR3.

The protective film INS may be disposed on the side of the first semiconductor layer SEM1, the side of the active layer MQW, the sides of the second semiconductor layer SEM2, and the conductive layer E1. The protective film INS may be a film to protect the side surface of the light emitting element LE. The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

The plurality of contact electrodes CTE1 and CTE2 may be disposed on the protective film INS. Each of the plurality of contact electrodes CTE1 and CTE2 may be disposed between the organic layer 210 and the protective film INS.

Each of the plurality of contact electrodes CTE1 and CTE2 may be connected to a conductive layer E1 that is exposed and not covered by the protective film INS. Accordingly, even if one of the plurality of contact electrodes CTE1 and CTE2 is not connected to the conductive layer E1 due to a process error, the occurrence of a defect in which the light-emitting element LE does not light up may be prevented by connecting the other contact electrode from among CTE1 and CTE2 to the conductive layer E1.

The plurality of contact electrodes CTE1 and CTE2 may be disposed on at least a portion of the side surface of the semiconductor stack STC. At least an area adjacent to the upper surface of the semiconductor stack STC from among the side surfaces of the semiconductor stack STC may be exposed and not covered by the contact electrodes CTE1 and CTE2. For example, the contact electrodes CTE1 and CTE2 are spaced (e.g., spaced apart) from the upper surface of the semiconductor stack STC in the third direction DR3.

When the plurality of contact electrodes CTE1 and CTE2 is formed of a metal with high reflectivity, light emitted from the active layer MQW of the light emitting element LE and traveling in the lateral direction of the light emitting element LE may be reflected by the plurality of contact electrodes CTE and emitted to the upper surface of the light emitting element LE. Therefore, because the loss of light from the light emitting element LE may be reduced, the light efficiency of the light emitting element LE may be increased. Therefore, it is preferable that each of the plurality of contact electrodes CTE1 and CTE2 is arranged to cover most of the lateral surface of the semiconductor stack STC to increase the light efficiency of the light emitting element LE.

The plurality of contact electrodes CTE1 and CTE2 may include molybdenum (Mo), aluminum (Al), chromium (Cr), gold (Au), titanium (Ti), nickel (Ni), neodymium (Nd), and/or copper (Cu). Specifically, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Upper sacrificial electrodes USC1 and USC2 are disposed between the contact electrodes CTE1 and CTE2 and the organic layer 210. The upper sacrificial electrodes USC1 and USC2 may be in direct contact with the organic layer 210.

The upper sacrificial electrodes USC1 and USC2 may be disposed on the contact electrodes CTE1 and CTE2 to overlap at least one side of the semiconductor stack STC and the lower surface. For example, the upper sacrificial electrodes USC1 and USC2 may be disposed on the contact electrodes CTE1 and CTE2 to overlap at least one side of the semiconductor stack STC and the lower surface of the conductive layer E1. Therefore, the upper sacrificial electrodes USC1 and USC2 may be electrically connected to the conductive layer E1 through the contact electrode CTE.

The upper sacrificial electrodes USC1 and USC2 may be formed of a metal having the same conductivity as the bottom sacrificial electrode BSC. For example, the upper sacrificial electrode USC may be formed of IZO.

The connection electrodes BE1 and BE2 connects the contact electrodes CTE1 and CTE2 of the light emitting element LE and the pixel electrodes PXE1, PXE2, and PXE3.

In one or more embodiments, the connection electrodes BE1 and BE2 are disposed on the contact electrodes CTE1 and CTE2 disposed on the side surface of the semiconductor stack STC and extends along the upper sacrificial electrodes USC1 and USC2 and the organic layer 210 to contact the reflective electrode SRF exposed by the bottom sacrificial electrode BSC, and the pixel electrodes PXE1, PXE2, and PXE3 exposed by the reflective electrode SRF. Accordingly, the connection electrodes BE1 and BE2 may connect the conductive layer E1 of the light emitting element LE and the pixel electrodes PXE1, PXE2, and PXE3.

The connection electrodes BE1 and BE2 may expose an area adjacent to the upper surface of the semiconductor stack STC from among the side surfaces of the semiconductor stack STC without being covered by the connection electrodes BE1 and BE2. In the third direction DR3, a separation distance between the top surface of the semiconductor stack STC and the connection electrodes BE1 and BE2 may be greater than a separation distance between the top surface of the semiconductor stack STC and the contact electrodes CTE1 and CTE2 in the third direction DR3, but the present disclosure is not limited thereto. For example, the separation distance between the top surface of the semiconductor stack STC and the connection electrodes BE1 and BE2 in the third direction DR3 may be smaller than a separation distance between the top surface of the semiconductor stack STC and the contact electrodes CTE1 and CTE2 in the third direction DR3. In this case, the connection electrodes BE1 and BE2 may cover at least a portion of the protective film INS that is exposed and not covered by the contact electrodes CTE1 and CTE2. Alternatively, the connection electrodes BE1 and BE2 may be arranged to cover the entirety of the protective film INS that is exposed and not covered by the contact electrodes CTE1 and CTE2. As another example, the separation distance between the top surface of the semiconductor stack STC and the connection electrodes BE1 and BE2 in the third direction DR3 may be substantially equal to the separation distance between the top surface of the semiconductor stack STC and the contact electrodes CTE1 and CTE2 in the third direction DR3.

The second organic film 211 may be disposed to cover a portion of the side surfaces of the plurality of light emitting elements LE. Further, the second organic film 211 may be disposed to cover the connection electrodes BE1 and BE2.

The third organic film 212 may be disposed on the second organic film 211. The third organic film 212 may be disposed to cover another portion of the side surface of each of the plurality of light emitting elements LE. The third organic film 212 may be disposed on the protective layer INS, the contact electrodes CTE1 and CTE2, and the connection electrodes BE1 and BE2 that are exposed and not covered by the second organic film 211, as shown in FIG. 16, but the present disclosure is not limited thereto. In one example, the entire connection electrodes BE1 and BE2 may be covered by the second organic film 211. The top surface of each of the plurality of light emitting elements LE may be exposed without being covered by the third organic film 212.

The second organic film 211 and the third organic film 212 are layers for flattening steps caused by the plurality of light emitting elements LE. When the height of the second organic film 211 is arranged to cover most of the side surfaces of each of the plurality of light emitting elements LE, the third organic film 212 may be omitted.

The second organic film 211 and the third organic film 212 may be formed from an organic film such as an acrylic resin, an epoxy resin, a phenolic resin, a polyamide resin, a polyimide resin, and/or the like.

The common electrode CE may be disposed on the top surface of each of the plurality of light emitting elements LE and the third organic film 212. The common electrode CE may be a common layer commonly formed in the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), which may transmit light.

The pixel electrodes PXE1, PXE2, and PXE3 may be referred to as an anode electrode or a first electrode, and the common electrode CE may be referred to as a cathode electrode or a second electrode.

The first capping layer CAP1 may be disposed on the common electrode CE.

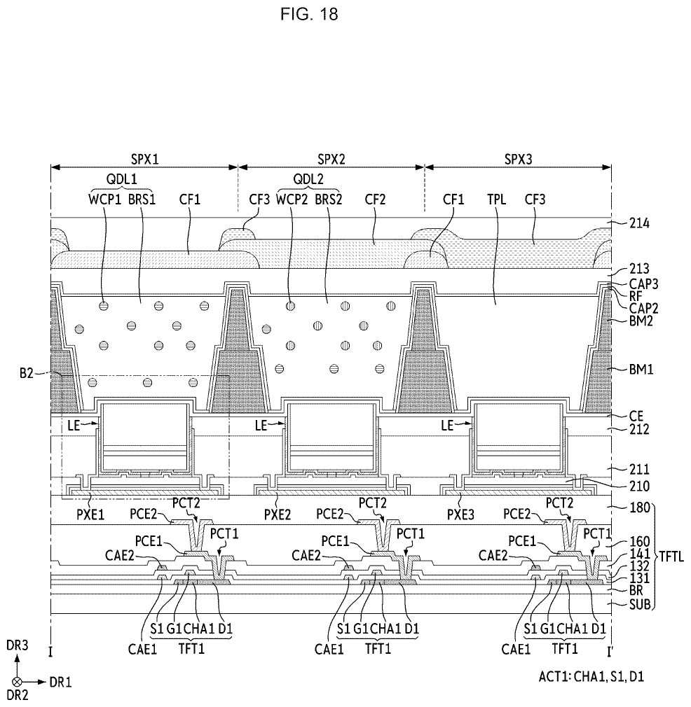

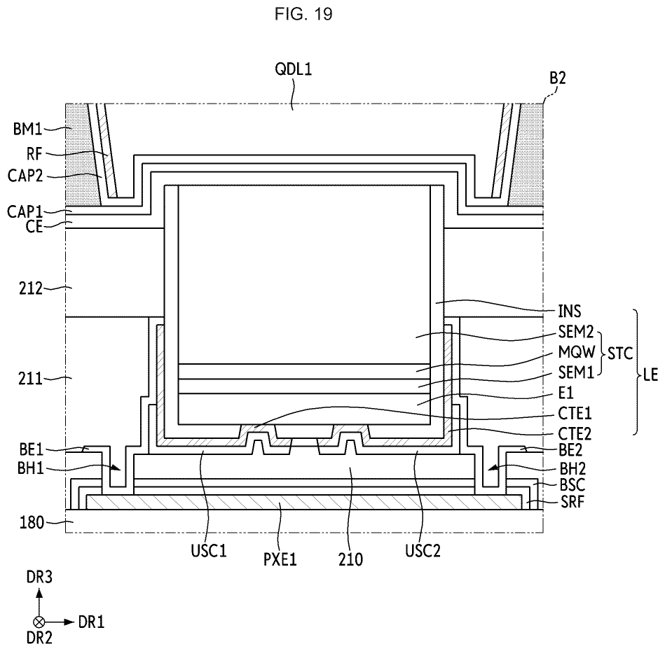

FIG. 18 is a cross-sectional view illustrating another example of a cross-section of the display panel corresponding to the line I1-I1′ in FIG. 16. FIG. 19 is a detailed cross-sectional view illustrating another example of an area B2 in FIG. 18.

The embodiments of FIGS. 18 and 19 differ from the embodiments of FIGS. 16 and 17 in that each of the organic layers 210 is formed to cover all of the pixel electrodes PXE1, PXE2, and PXE3 and has connection holes BH1 and BH2 penetrating the organic layer 210. In the embodiments of FIGS. 18 and 19, descriptions that overlap with those of the embodiments of FIGS. 16 and 17 will not be repeated, and differences from the embodiments of FIGS. 16 and 17 will be mainly described.

The organic layer 210 may be disposed on the entire surface of the pixel electrode layer to cover all the pixel electrodes PXE1, PXE2, and PXE3.

The connection holes BH1 and BH2 penetrates the bottom sacrificial electrode BSC and the reflective electrode SRF to expose at least a portion of the pixel electrodes PXE1, PXE2, and PXE3.

The connection electrodes BE1 and BE2 connect the contact electrodes CTE1 and CTE2 of the light emitting element LE and the pixel electrodes PXE1, PXE2, and PXE3. The connection electrodes BE1 and BE2 may be connected to the pixel electrodes PXE1, PXE2, and PXE3 through the connection holes BH1 and BH2 penetrating the organic layer 210, the bottom sacrificial electrode BSC, and the reflective electrode SRF. For example, the connection electrodes BE1 and BE2 may contact the pixel electrodes PXE1, PXE2, and PXE3 exposed through the connection holes BH1 and BH2.

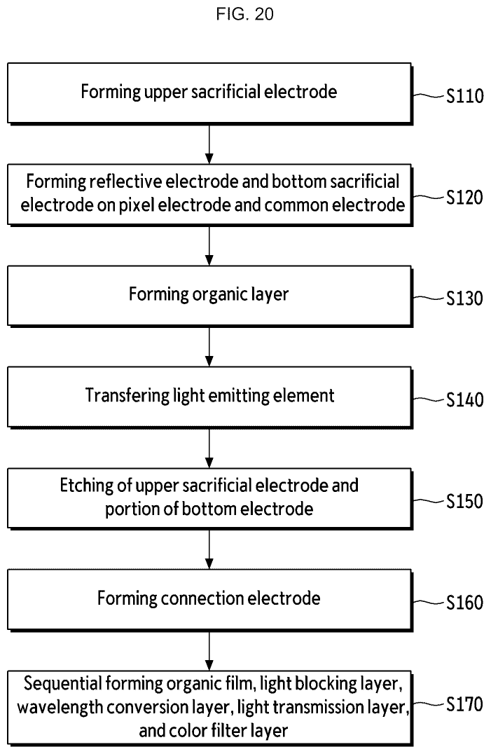

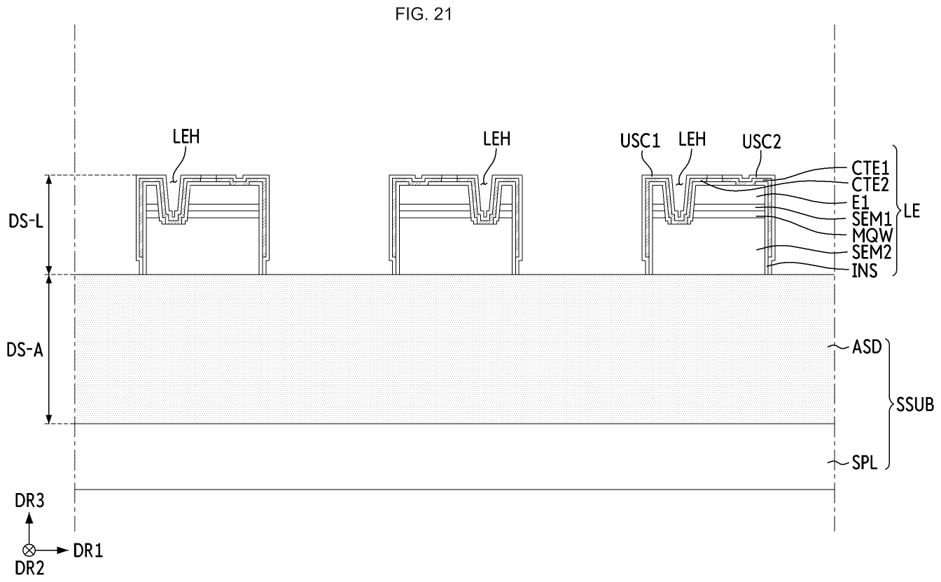

FIG. 20 is a flowchart illustrating a method of manufacturing a display device according to one or more embodiments. FIGS. 21-33 are example drawings to illustrate a method of manufacturing a display device according to one or more embodiments.

Hereinafter, a method for manufacturing a display device according to one or more embodiments will be described in detail by conjunction FIG. 20 with FIGS. 21-33. In FIGS. 21-33, cross-sections corresponding to the lines I-I′ of FIG. 6 are illustrated for convenience of explanation.

First, as in FIG. 21, an upper sacrificial electrode covering one side and a side surface of a light emitting element LE is formed. (S110 of FIG. 20)

The light emitting element LE is an element grown on a semiconductor substrate and may be the light emitting element LE described with reference to FIGS. 6 and 7.

The semiconductor substrate may be a silicon wafer substrate or a sapphire substrate. The light emitting element LE grown on the semiconductor substrate may be transferred onto a substrate SUB of a display panel through one or more intermediate substrates.

The upper sacrificial electrodes USC1 and USC2 may be formed on the light emitting element LE.

For example, a sacrificial electrode material layer may be deposited on the entire surface of a semiconductor substrate to cover the entire light emitting element LE.

Thereafter, the sacrificial electrode material layer is patterned to form the first upper sacrificial electrode USC1 and the second upper sacrificial electrode USC2.

The light emitting element grown on the semiconductor substrate is transferred onto the first substrate SSUB. The light emitting element may be transferred onto the first substrate SSUB by a stamp or the like or may be transferred onto the first substrate SSUB through another relay substrate.

The first substrate SSUB may include a support layer SPL and an adhesive layer ASD. The support layer SPL may be made of a material that is transparent and mechanically stable so that light may pass through. For example, the support layer SPL may include a transparent polymer such as polyester, polyacrylic, polyoxy, polyethylene, polystyrene, polyethylene terephthalate, and/or the like.

An adhesive layer ASD having an adhesive force may be disposed on the support layer SPL.

The thickness DS-A of the adhesive layer ASD may be thicker than the height DS-L of the light emitting element LE. For example, the thickness of the adhesive layer ASD may be about 50 μm.

The adhesive layer ASD may include an adhesive material for bonding the light emitting element LE. For example, the adhesive material may be a siloxane-based organic polymer, such as an organosilicon compound such as polydimethylsiloane (PDMS). The adhesive material may have fluidity.

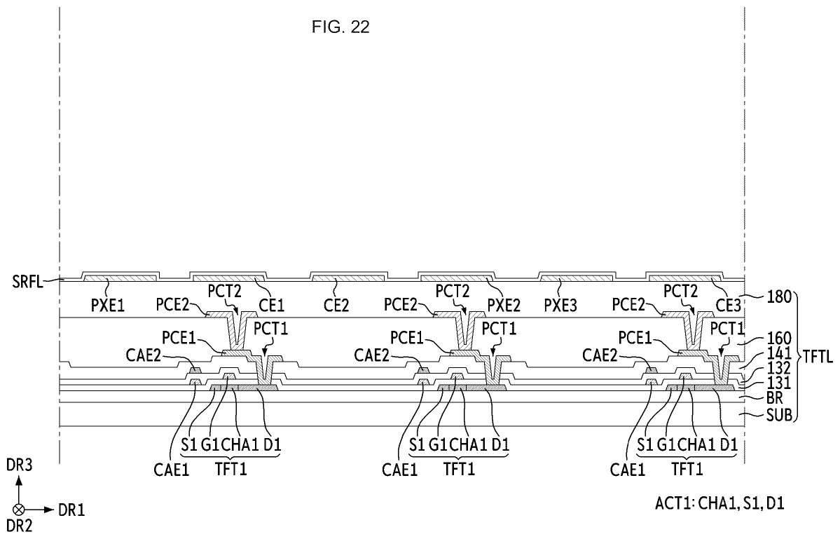

Second, as shown in FIGS. 22-24, reflective electrodes SRF1 and SRF2 and bottom sacrificial electrodes BSC1 and BSC2 are formed on the pixel electrodes PXE1, PXE2, and PXE3 and the common electrodes CE1, CE2, and CE3. (S120 of FIG. 20)

The reflective material layer SRFL and the sacrificial material layer BSCL may be sequentially deposited on the entire surface of the pixel electrodes PXE1, PXE2, and PXE3 and the common electrodes CE1, CE2, and CE3.

For example, referring to FIG. 22, the reflective material layer SRFL may be deposited on the entire surface of the substrate SUB. The reflective material layer SRFL may be formed to cover the pixel electrodes PXE1, PXE2, and PXE3 and the common electrodes CE1, CE2, and CE3. The reflective material layer SRFL may be formed on one surface of the semiconductor substrate SSUB exposed between the pixel electrodes PXE1, PXE2, and PXE3 and the common electrodes CE1, CE2, and CE3.

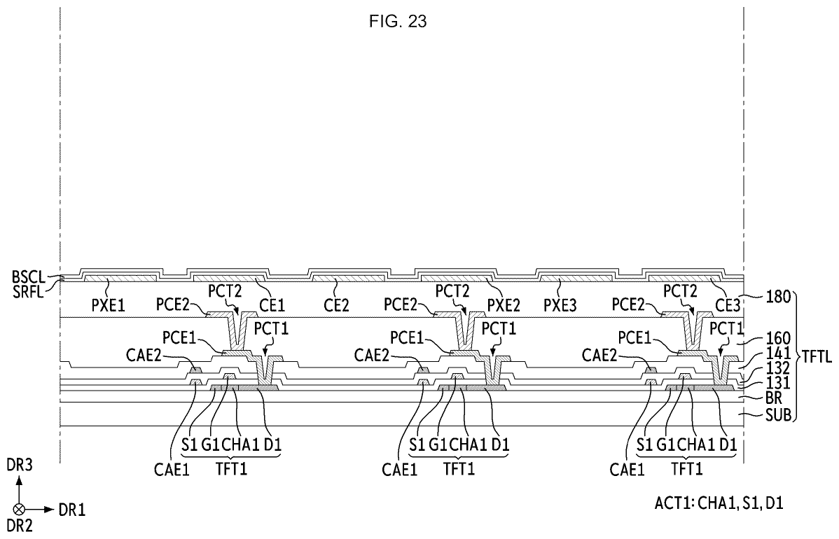

Next, referring to FIG. 23, a sacrificial material layer BSCL may be fully deposited on one side of the substrate SUB to cover the reflective material layer SRFL.

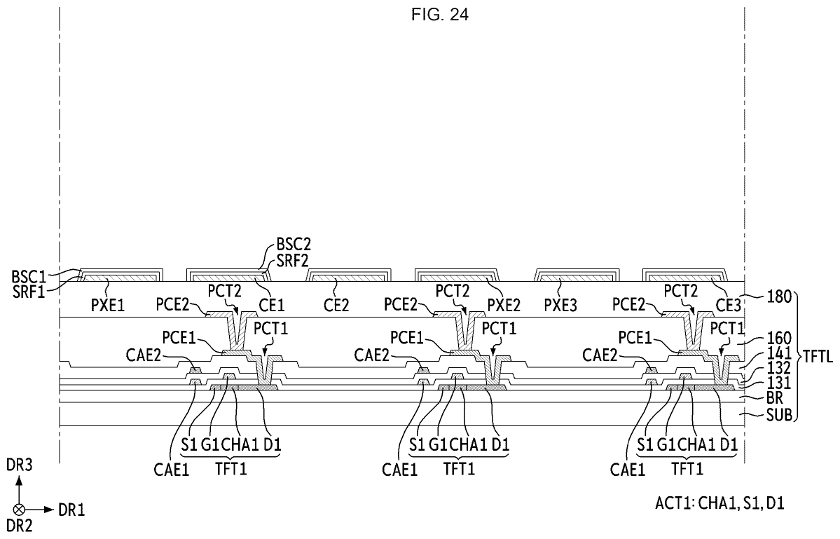

Thereafter, referring to FIG. 24, the sacrificial material layer BSCL and the reflective material layer SRFL may be patterned in the same process. For example, the mask pattern may be formed not to cover the sacrificial material layer BSCL that does not overlap the pixel electrodes PXE1, PXE2, and PXE3 and the common electrodes CE1, CE2, and CE3.

If the sacrificial material layer BSCL not covered by the relay substrate mask pattern is wet-etched, the sacrificial material layer BSCL may be etched by the same mask pattern without a separate additional photo process, thereby allowing the exposed reflective material layer SRFL to be wet-etched. The first chemical used in the wet-etching may react with both the sacrificial material layer BSCL and the reflective material layer SRFL.

Thus, the sacrificial material layer BSCL and the reflective material layer SRFL disposed between the pixel electrodes PXE1, PXE2, and PXE3 and the common electrodes CE1, CE2, and CE3 are etched, thereby exposing the semiconductor substrate SSUB. Further, the reflective electrodes SRF1 and SRF2 and the sacrificial electrodes BSC1 and BSC2 may be sequentially formed on the pixel electrodes PXE1, PXE2, and PXE3 and the common electrodes CE1, CE2, and CE3. The mask pattern may be removed by an ashing process after forming the reflective electrodes SRF1 and SRF2 and the sacrificial electrodes BSC1 and BSC2 thereon.

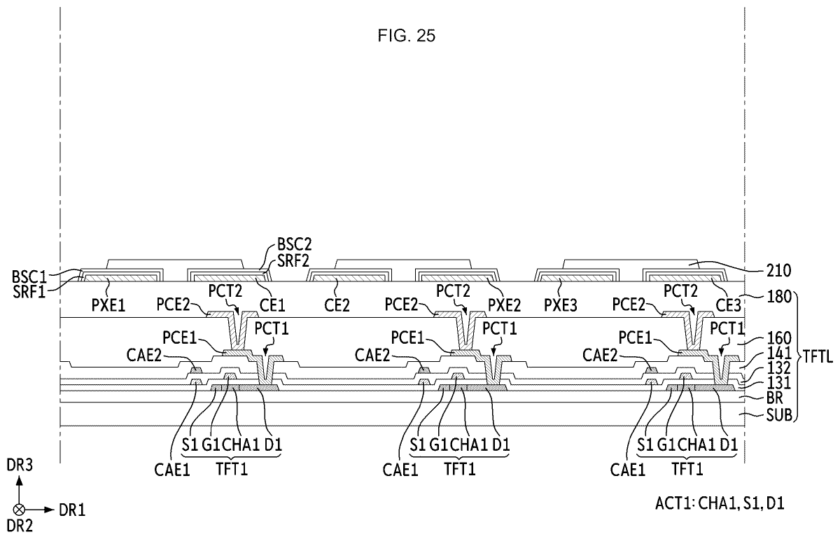

Third, referring to FIG. 25, an organic layer 210 is formed. (S130 of FIG. 20)

Referring to FIG. 25, the organic layer 210 may be formed to cover at least a portion of the sacrificial electrodes BSC1 and BSC2, the pixel electrodes PXE1, PXE2, and PXE3 and the common electrodes CE1, CE2, and CE3 on one surface of the substrate SUB.

If the organic layer 210 is a photosensitive organic film such as a photoresist, the organic layer 210 may be soft baked at the first temperature.

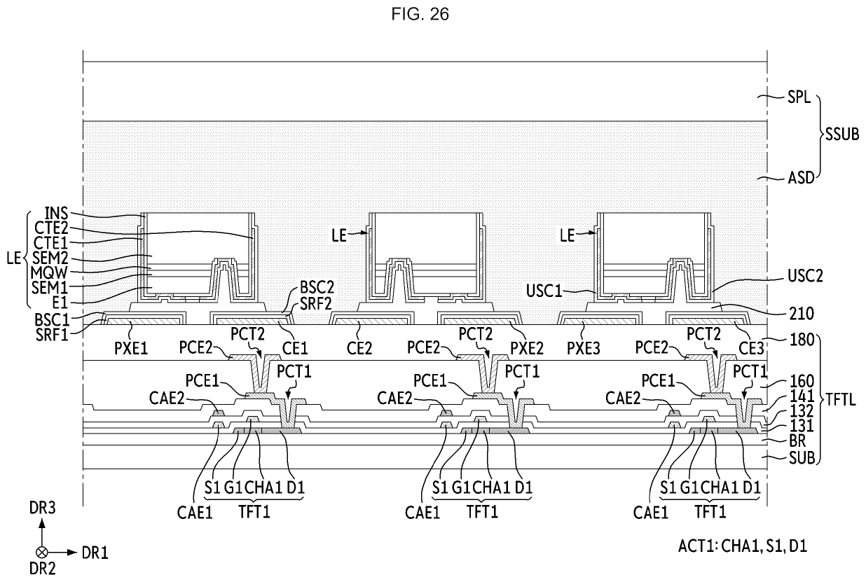

Fourth, referring to FIG. 26 and FIG. 27, the light emitting element LE on the first substrate SSUB is transferred to the organic layer 210, and the first substrate SSUB is removed. (S140 of FIG. 20)

For example, referring to FIG. 26, the first substrate SSUB is placed on the substrate SUB so that the light emitting element LE on the first substrate SSUB faces the organic layer 210. Then, the light emitting element LE is thermally bonded on the organic layer 210. Accordingly, at least a portion of the light emitting element LE may be temporarily fixed by being embedded in the organic layer 210. When the fluidity of the organic layer 210 is small or the organic layer 210 is rigid, the depth at which the light emitting element LE is inserted or embedded in the organic layer 210 may be very small, or the light emitting element LE may be placed on the organic layer 210 without being inserted or embedded in the organic layer 210. Then, the organic layer 210 may be completely cured at a second temperature higher than the first temperature. The first temperature may be approximately 100 Celsius degrees, and the second temperature may be approximately 230 Celsius degrees, but the present disclosure is not limited thereto. Furthermore, the process of completely curing the organic layer 210 at the second temperature may be performed for approximately 30 minutes.

In addition, because the adhesive layer ASD has fluidity and elasticity, the light emitting element LE may be embedded into the adhesive layer ASD during heat pressing, so that the adhesive material of the adhesive layer ASD not only fills the space between the light emitting elements LE, but also may come into contact with the upper and side surfaces of the organic layer 210, the upper surface of the bottom sacrificial electrode BSC1 and BSC2, and the side surfaces of the upper sacrificial electrode USC1 and USC2.

On the other hand, the adhesive layer ASD may be partially melted during heat pressing, leaving residual particles on the surface (e.g., the upper and side surfaces of the organic layer 210, the upper surface of the bottom sacrificial electrode BSC1 and BSC2, and the side surfaces of the upper sacrificial electrode USC1 and USC2) that contact the adhesive layer ASD. The residual particles are by-products generated during the process and are one of the contaminants. Therefore, the residual particles may be referred to as the contaminant particles REP.

Thereafter, the first substrate SSUB may be separated from the light emitting element LE and removed. For example, a laser is irradiated to a desired light emitting element LE considering the spacing between the plurality of light emitting elements LE arranged on the first substrate SSUB. The adhesive strength of the adhesive layer attached to the light emitting element LE to which the laser is irradiated may be reduced, so that the light emitting element LE and the first substrate SSUB may be physically or naturally separated.

After the first substrate SSUB is separated, the contaminant particles REP may be attached to the upper and side surfaces of the organic layer 210 to which the adhesive material was adhered, the upper surface of the bottom sacrificial electrodes BSC1 and BSC2, and the side surfaces of the upper sacrificial electrodes USC1 and USC2. When an electrode is formed on the upper surface of the contaminant particles REP in this way, a conductivity problem may occur between the upper conductor and the lower conductor with the contaminant particles REP in between. The conductivity problems may be, for example, increased contact resistance and increased scattering of resistance. Such a conductivity problem may cause a dark spot when the display panel is turned on and may reduce the reliability of the display panel.

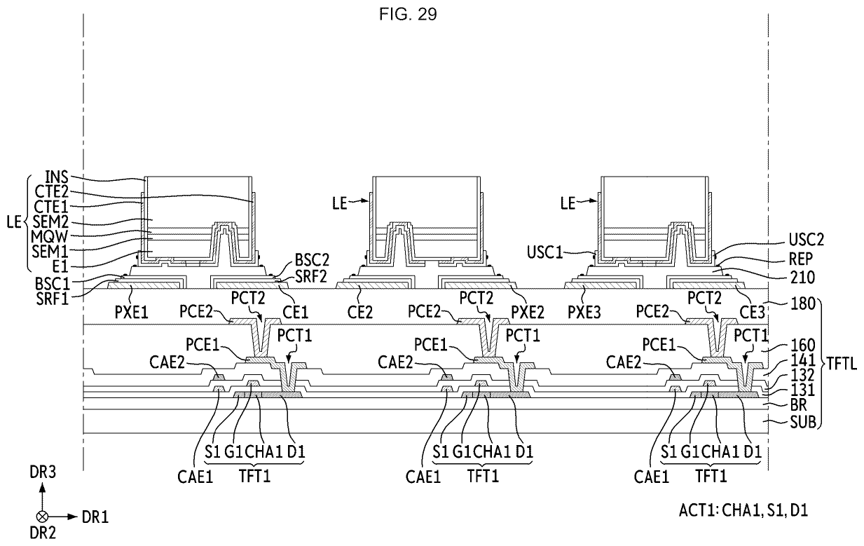

Fifth, referring to FIGS. 28 and 29, a portion of the upper sacrificial electrodes USC1 and USC2 and the bottom sacrificial electrodes BSC1 and BSC2 are etched. (S150 of FIG. 20)

A photoresist PR1 is formed to cover a portion of the upper sacrificial electrodes USC1 and USC2, the organic layer 210, and the bottom sacrificial electrodes BSC1 and BSC2 disposed on the side of the light emitting element LE.

The upper sacrificial electrodes USC1 and USC2 and the bottom sacrificial electrodes BSC1 and BSC2 not covered by the photoresist PR1 may be formed by wet etching but is not limited thereto.

At this time, the reflective electrodes SRF1 and SRF2 below the bottom sacrificial electrodes BSC1 and BSC2 may be etched together to expose at least a portion of the pixel electrode layer.

A portion of the upper sacrificial electrodes USC1 and USC2 may be etched to expose the contact electrodes CTE1 and CTE2. The surfaces of the upper sacrificial electrodes USC1 and USC2 are etched with contaminant particles REP, while the surfaces of the contact electrodes CTE1 and CTE2 are not etched with contaminant particles REP. Similarly, the surfaces of the bottom sacrificial electrodes BSC1 and BSC2 are etched with contaminant particles REP, while the surfaces of the pixel electrodes PXE1, PXE2, and PXE3 and the common electrodes CE1, CE2, and CE3 are not etched with contaminant particles REP.

On the other hand, by controlling the etchant or the etching time, the degree of etching of the bottom sacrificial electrodes BSC1 and BSC2 and the upper sacrificial electrodes USC1 and USC2 may be controlled. For example, by etching only the upper surfaces of the bottom sacrificial electrodes BSC1 and BSC2 and the upper sacrificial electrodes USC1 and USC2 and then stopping the etching, the thickness of the bottom sacrificial electrodes BSC1 and BSC2 and the upper sacrificial electrodes USC1 and USC2 may be formed thinner in some areas, as described with reference to FIG. 9. Because the contaminant particles REP are attached only to the upper surfaces of the bottom sacrificial electrodes BSC1 and BSC2 and the upper sacrificial electrodes USC1 and USC2, even when only the upper surfaces of the bottom sacrificial electrodes BSC1 and BSC2 and the upper sacrificial electrodes USC1 and USC2 are etched, the possibility of causing dark spots when the display panel is lit due to the contaminant particles may be reduced and the reliability of the panel may be improved, similar to the embodiment of FIG. 6. In another example, by etching only the bottom sacrificial electrodes BSC1 and BSC2 and then stopping the etching, the reflective electrodes SRF1 and SRF2 may prevent the pixel electrodes PXE1, PXE2, and PXE3 and the common electrodes CE1, CE2, and CE3 from being exposed, as described with reference to FIG. 8.

Then, the photoresist PR1 may be removed by an ashing process.

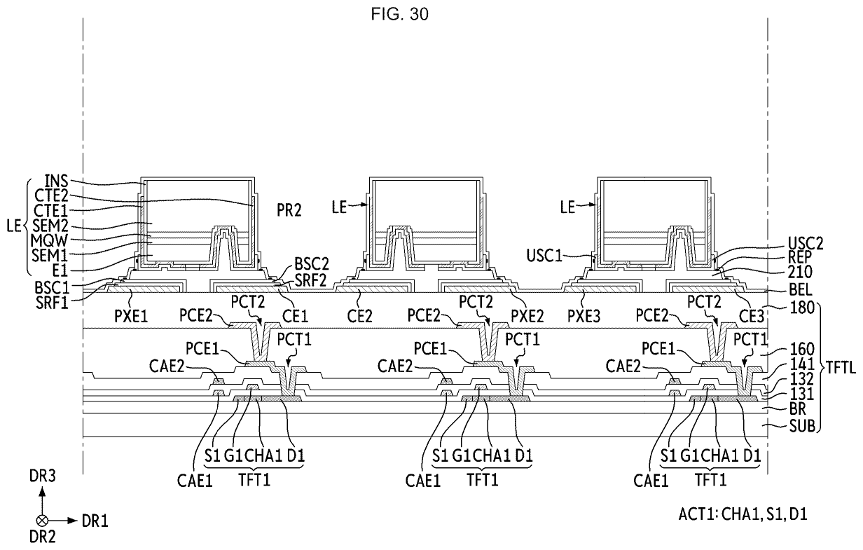

Sixth, referring to FIGS. 30-32, first connection electrodes BE1 for connecting the first contact electrode CTE1 of the light emitting element LE and the pixel electrodes PXE1, PXE2, and PXE3 and second connection electrodes BE2 for connecting the second contact electrode CTE2 and the common electrodes CE1, CE2, and CE3 are formed. (S160 of FIG. 20)

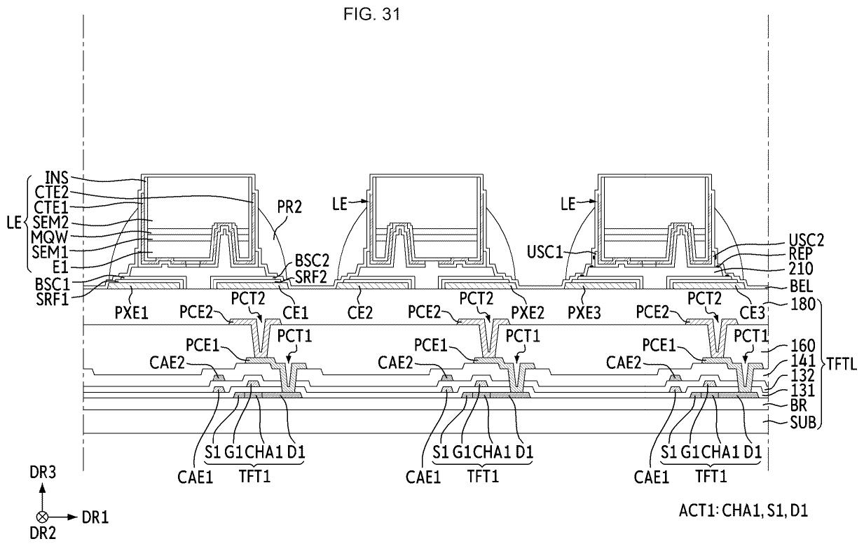

Referring to FIG. 30, a connection electrode material layer BEL is deposited to cover the light emitting element LE. Then, referring to FIG. 31, a portion of the connection electrode material layer BEL is etched using a photoresist PR2 to form the first connection electrode BE1 and the second connection electrode BE2.

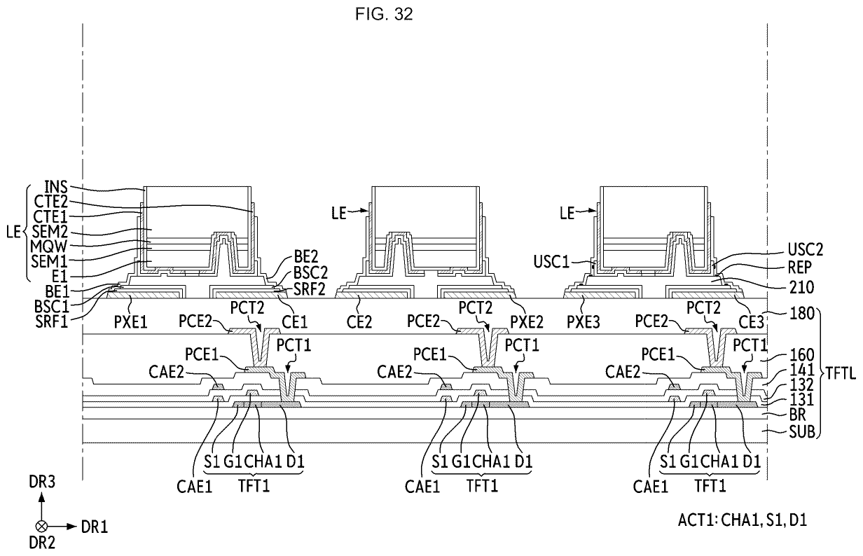

Referring to FIG. 32, the first connection electrodes BE1 may directly contact the first contact electrode CTE1 on the side of the light emitting element LE and may directly contact the pixel electrodes PXE1, PXE2, and PXE3. The second connection electrodes BE2 may directly contact the second contact electrode CTE2 on the side of the light emitting element LE and may directly contact the common electrodes CE1, CE2, and CE3.

In this way, because there are no contaminant particles REP between the contact surface of the first connection electrode BE1 and the first contact electrode CTE1, the contact surface of the first connection electrode BE1 and the pixel electrodes PXE1, PXE2, and PXE3, the contact surface of the second connection electrode BE2 and the second contact electrode CTE2, and the contact surface of the second connection electrode BE2 and the common electrodes CE1, CE2, and CE3, the respective contact surfaces may contact each other without being lifted. In this way, the possibility of causing dark spots on the display panel may be reduced or minimized or prevented.

Seventh, an organic film, a light blocking layer, a wavelength conversion layer, a light transmission layer, and a color filter layer are formed sequentially. (S170 of FIG. 20)

Referring to FIG. 33, a second organic film 211 and a third organic film 212 are formed to fix the light emitting elements LE and to flatten the steps caused by the light emitting elements LE.

Then, a first capping layer CAP1 is formed on the third organic film 212 and the light emitting elements LE, and a first light blocking layer BM1 and a second light blocking layer BM2 are formed on the first capping layer CAP1 not to overlap with the light emitting elements LE in the third direction DR3. Then, a second capping layer CAP2 covering the first light blocking layer BM1, the second light blocking layer BM2, and the first capping layer CAP1 is formed. Then, a reflective film RF is formed to cover the second capping layer CAP2 disposed on the first light blocking layer BM1 and the second light blocking layer BM2.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CAP3 is formed covering the first light conversion layers QDL1, the second light conversion layers QDL2, and the light transmission layers TPL. Then, a fourth organic film 213 is formed on the third capping layer CAP3.

Then, a first color filter CF1 is formed on the fourth organic film 213 overlapping the first light conversion layers QDL1 in the third direction DR3, a second color filter CF2 is formed overlapping the second light conversion layers QDL2 in the third direction DR3, and a third color filter CF3 is formed overlapping the light transmission layers TPL in the third direction DR3. The first color filter CF1, the second color filter CF2, and the third color filter CF3 may all be formed in the region overlapping the first light blocking layer BM1 and the second light blocking layer BM2 in the third direction DR3.

Then, a fifth organic film 214 is formed on the first color filter CF1, the second color filter CF2, and the third color filter CF3.

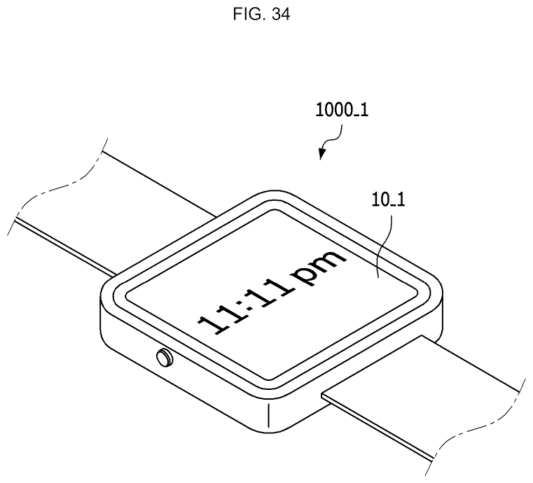

FIG. 34 is an example drawing illustrating a smart watch including a display device according to one or more embodiments.

Referring to FIG. 34, the display device 10_1 according to one or more embodiments may be applied to a smart watch 1000_1, which is one of smart devices.

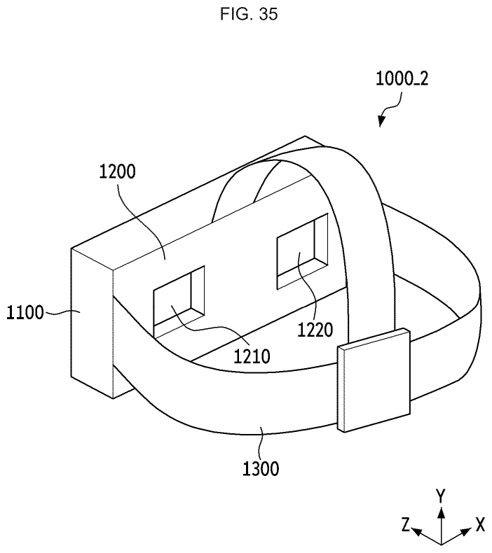

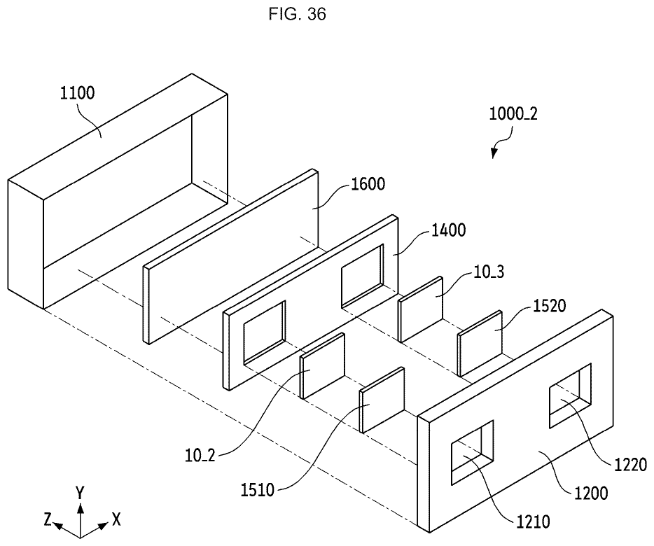

FIGS. 35 and 36 are example drawings illustrating a virtual reality device including a display device according to one or more embodiments.

Referring to FIGS. 35 and 36, a head-mounted display device 1000_2 according to one or more embodiments includes a first display device 10_2, a second display device 10_3, a display device storage portion 1100, a storage portion cover 1200, a first eyepiece lens 1210, a second eyepiece lens 1220, a head-mounted band 1300, a middle frame 1400, a first optical member 1510, a second optical member 1520, and a control circuit board 1600.

The first display device 10_2 provides an image to the user's left eye, and the second display device 10_3 provides an image to the user's right eye. Because each of the first display device 10_2 and the second display device 10_3 is substantially the same as the display device 10 described in connection with FIG. 1 and FIG. 2, the description of the first display device 10_2 and the second display device 10_3 will be omitted.

The first optical member 1510 may be disposed between the first display device 10_2 and the first eyepiece lens 1210. The second optical member 1520 may be disposed between the second display device 10_3 and the second eyepiece lens 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 serves to support and fix the first display device 10_2, the second display device 10_3, and the control circuit board 1600.

The control circuit board 1600 may be disposed between the middle frame 1400 and the display device storage portion 1100. The control circuit board 1600 may be connected to the first display device 10_2 and the second display device 10_3 through a connector. The control circuit board 1600 may convert an image source input from the outside into digital video data DATA and transmit the digital video data DATA to the first display device 10_2 and the second display device 10_3 through the connector.

The control circuit board 1600 may transmit digital video data DATA corresponding to a left-eye image optimized for the user's left eye to the first display device 10_2, and digital video data DATA corresponding to a right-eye image optimized for the user's right eye to the second display device 10_3. Alternatively, the control circuit board 1600 may transmit the same digital video data DATA to the first display device 10_2 and the second display device 10_3.

The display device storage portion 1100 serves to store the first display device 10_2, the second display device 10_3, the middle frame 1400, the first optical member 1510, the second optical member 1520, and the control circuit board 1600. The storage portion cover 1200 is disposed to cover an open surface of the display device storage portion 1100. The storage portion cover 1200 may include a first eyepiece 1210 for the user's left eye and a second eyepiece 1220 for the user's right eye. In FIGS. 33 and 34, the first eyepiece 1210 and the second eyepiece 1220 are separately disposed, but the present disclosure is not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Accordingly, the user may view the image of the first display device 10_2 magnified into a virtual image by the first optical member 1510 through the first eyepiece 1210 and may view the image of the second display device 10_3 magnified into a virtual image by the second optical member 1520 through the second eyepiece 1220.

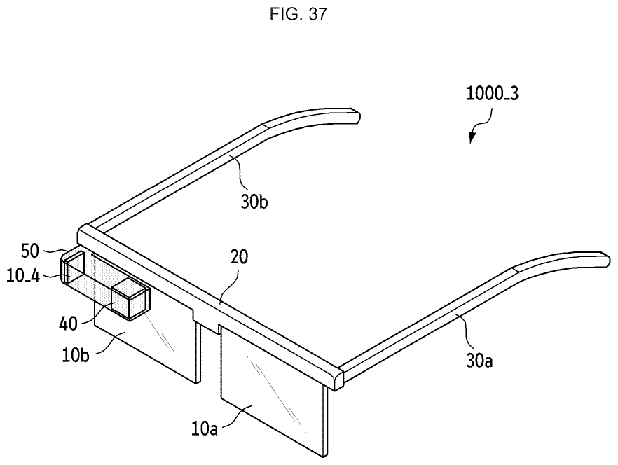

The head-mounted band 1300 serves to secure the display device storage portion 1100 to the user's head so that the first eyepiece 1210 and the second eyepiece 1220 of the storage portion cover 1200 may be maintained in a state where they are respectively arranged on the user's left and right eyes. If the display device storage portion 1200 is implemented as lightweight and compact, the head-mounted display device 1000 may be equipped with a glasses frame as shown in FIG. 37 instead of the head-mounted band 1300.

In addition, the head-mounted display device 1000 may further be equipped with a battery for supplying power, an external memory slot for storing external memory, and an external connection port and a wireless communication module for receiving a video source. The external connection port may be a universe serial bus (USB) terminal, a display port, or a high-definition multimedia interface (HDMI) terminal, and the wireless communication module may be a 5G communication module, a 4G communication module, a wifi module, and/or a Bluetooth module.

FIG. 37 is an example drawing illustrating a virtual reality device including a display device according to one or more embodiments. FIG. 37 illustrates a virtual reality device 1000_3 to which a display device 10_4 according to one or more embodiments is applied.

Referring to FIG. 37, a virtual reality device 1000_3 according to one or more embodiments may be a device in the form of glasses. The virtual reality device 1000_3 according to one or more embodiments may include a display device 10_4, a left-eye lens 10a, a right-eye lens 10b, a support frame 20, eyeglass frame legs 30a and 30b, a reflective member 40, and a display device storage portion 50.

In FIG. 37, it is exemplified that the virtual reality device 1000_3 is a glasses-type display device including eyeglass frame legs 30a and 30b. That is, the virtual reality device 1000_3 according to one or more embodiments is not limited to that illustrated in FIG. 37 and may be applied in various forms in various other electronic devices.

The display device storage portion 50 may include a display device 10_4 and a reflective member 40. The image displayed on the display device 10_4 may be reflected from the reflective member 40 and provided to the user's right eye through the right eye lens 10b. As a result, the user may view the virtual reality image displayed on the display device 10_4 through the right eye.

In FIG. 37, the display device storage portion 50 is disposed at the right end of the support frame 20, but the present specification is not limited thereto. For example, the display device storage portion 50 may be disposed at the left end of the support frame 20, and in this case, the image displayed on the display device 10_4 may be reflected from the reflective member 40 and provided to the user's left eye through the left eye lens 10a. As a result, the user may view the virtual reality image displayed on the display device 10_4 through the left eye. Alternatively, the display device storage portion 50 may be disposed at both the left end and the right end of the support frame 20, in which case the user may view the virtual reality image displayed on the display device 10_4 through both the left and right eyes.

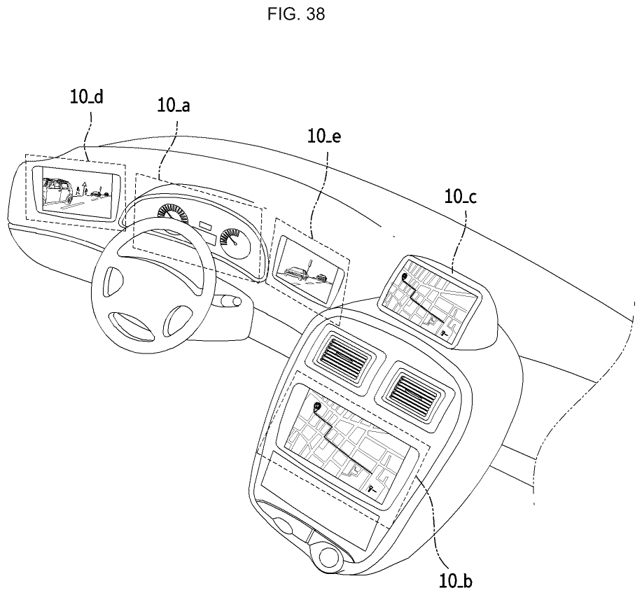

FIG. 38 is an example drawing illustrating a vehicle instrument panel and center fascia including display devices according to one or more embodiments. FIG. 38 illustrates a vehicle to which display devices 10_a, 10_b, 10_c, 10_d, and 10_e according to one or more embodiments are applied.

Referring to FIG. 38, the display devices 10_a, 10_b, and 10_c according to one or more embodiments may be applied to an instrument panel of the vehicle, applied to the center fascia of the vehicle, or applied to a center information display (CID) disposed on the dashboard of the vehicle. Further, the display devices 10_d and 10_e according to one or more embodiments may be applied to a room mirror display that replaces a side mirror of a vehicle.

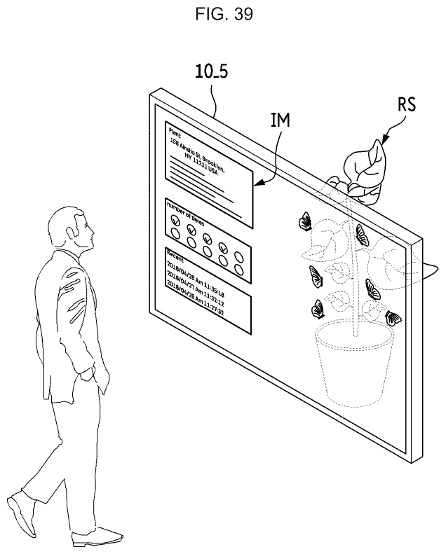

FIG. 39 is an example drawing illustrating a transparent display device including a display device according to one or more embodiments.

Referring to FIG. 39, the display device 10_5 according to one or more embodiments may be applied to a transparent display device. The transparent display device may display an image IM and transmit light at the same time. Therefore, a user positioned at the front of the transparent display device may not only view the image IM displayed on the display device 10_5, but also view an object RS or background positioned at the back of the transparent display device. When the display device 10_5 is applied to a transparent display device, the substrate of the display device 10_5 may include a light transmitting portion that may transmit light or may be formed of a material that may transmit light.

Although the embodiments of the present disclosure have been described with reference to the attached drawings, those skilled in the art will understand that the present disclosure may be implemented in other specific forms without changing the technical idea or essential features of the present disclosure. Therefore, it should be understood that the embodiments described above are examples in all respects and are not intended to be limiting.

What is claimed is:

1. A display device comprising:
a substrate;
a pixel electrode and a common electrode spaced from each other on the substrate;
a first reflective electrode on the pixel electrode and a second reflective electrode on the common electrode, respectively;
a first bottom sacrificial electrode on the first reflective electrode and a second bottom sacrificial electrode on the second reflective electrode;
an organic layer covering at least a portion of the first and second bottom sacrificial electrodes;
a light emitting element on the organic layer and comprising a semiconductor stack, a first contact electrode and a second contact electrode;
a first connection electrode connecting the pixel electrode and the first contact electrode and a second connection electrode connecting the common electrode and the second contact electrode; and
a first upper sacrificial electrode between the first contact electrode and the organic layer, and a second upper sacrificial electrode between the second contact electrode and the organic layer.

2. The display device of claim 1, wherein the first contact electrode and the second contact electrode are on a bottom surface and a side surface of the semiconductor stack, respectively, and are spaced from a top surface of the semiconductor stack by a first separation distance.

3. The display device of claim 2, wherein the first upper sacrificial electrode and the second upper sacrificial electrode are on a bottom surface and a side surface of the semiconductor stack, respectively, and are spaced from the top surface of the semiconductor stack by a second separation distance, wherein the second separation distance is greater than the first separation distance.

4. The display device of claim 2, wherein the first contact electrode is in direct contact with the first connection electrode on a side of the semiconductor stack, and the second contact electrode is in direct contact with the second connection electrode on a side of the semiconductor stack.

5. The display device of claim 1, wherein the light emitting element completely overlaps the first upper sacrificial electrode and the second upper sacrificial electrode.

6. The display device of claim 1, wherein the first bottom sacrificial electrode exposes at least a portion of the first reflective electrode, and the second bottom sacrificial electrode exposes at least a portion of the second reflective electrode.

7. The display device of claim 6, wherein the first connection electrode is in direct contact with the exposed pixel electrode, and the second connection electrode in direct contact with the exposed common electrode.

8. The display device of claim 7, wherein the first connection electrode is in direct contact with the exposed pixel electrode, and the second connection electrode is in direct contact with the exposed common electrode.

9. The display device of claim 1, wherein the light emitting element further comprises:
a conductive layer between the organic layer and the semiconductor stack; and
a protective film on side surfaces of the conductive layer and side surfaces of the semiconductor stack,
wherein the first contact electrode is on the protective film and is connected to the conductive layer that is exposed without being covered by the protective film,
wherein the second contact electrode is on the protective film and is in a hole penetrating the conductive layer and a portion of the semiconductor stack.

10. The display device of claim 1, wherein the organic layer covers the entire surface of the first bottom sacrificial electrode and the second bottom sacrificial electrode, the organic layer includes a first connection hole penetrating the first bottom sacrificial electrode and a second connection hole penetrating the organic layer and the second bottom sacrificial electrode,
wherein the first connection electrode connects the pixel electrode and the first contact electrode through the first connection hole,
wherein the second connection electrode connects the common electrode and the second contact electrode through the second connection hole.

11. The display device of claim 1, wherein the semiconductor stack further comprises:
a first semiconductor layer on the organic layer and comprising a semiconductor material layer doped with a first conductive dopant;
an active layer on the first semiconductor layer; and
a second semiconductor layer on the active layer and comprising a semiconductor material layer doped with a second conductive dopant.

12. A display device comprising:
a substrate;
a pixel electrode on the substrate;
a reflective electrode on each of the pixel electrodes;
a bottom sacrificial electrode on the reflective electrode;
an organic layer on the bottom sacrificial electrode; and
a light emitting element on the organic layer and comprising a semiconductor stack and a contact electrode;
a connection electrode connecting the pixel electrode and the contact electrode; and
an upper sacrificial electrode between the contact electrode and the organic layer.

13. The display device of claim 12, wherein the contact electrode is on a bottom surface and the side surface of the semiconductor stack, and is spaced from the top surface of the semiconductor stack by a first separation distance,
wherein the upper sacrificial electrode is on a bottom surface and a side surface of the semiconductor stack, respectively, and is spaced from the top surface of the semiconductor stack by a second separation distance, wherein the second separation distance is greater than the first separation distance.

14. The display device of claim 12, wherein the contact electrode is in direct contact with the connection electrode on a side surface of the semiconductor stack.

15. The display device of claim 12, wherein the bottom sacrificial electrode exposes at least a portion of the reflective electrode,
wherein the reflective electrode exposes at least a portion of the pixel electrode.

16. The display device of claim 15, wherein the connection electrode directly contacts the exposed pixel electrode.

17. The display device of claim 12, wherein the light emitting element further comprises,
a conductive layer between the organic layer and the semiconductor stack; and
a protective film on side surfaces of the conductive layer and side surfaces of the semiconductor stack,
wherein the contact electrode is on the protective film and is connected to the conductive layer exposed without being covered by the protective film,
wherein a connection hole penetrating the organic layer and the first bottom sacrificial electrode is included when the organic layer covers the entire surface of the bottom sacrificial electrode,
wherein the connection electrode connects the pixel electrode and the contact electrode through the connection hole.

18. A method for manufacturing a display device comprising:
forming an upper sacrificial electrode covering one side and a side surface of a light emitting element, and disposing the light emitting element on an adhesive layer applied on a first substrate, wherein the light emitting element comprises a semiconductor stack, a first contact electrode, and a second contact electrode;
forming a second substrate on which a pixel electrode and a common electrode are located, the pixel electrode and common electrode being formed to sequentially stack first and second reflective electrodes and first and second bottom sacrificial electrodes, respectively;
forming an organic layer covering at least a portion of the first and second sacrificial electrodes;
transferring the light emitting elements onto the organic layer so that the first and second contact electrodes of each of the light emitting elements face the pixel electrodes and the common electrodes;
forming a mask covering a portion of the bottom sacrificial electrode and the upper sacrificial electrode and etching the mask to expose at least a portion of the reflective electrode and at least a portion of the first and second contact electrodes; and
forming a first connection electrode connecting the pixel electrode and the first contact electrode through an exposed first contact electrode and the first reflective electrode, and a second connection electrode connecting the common electrode and the second contact electrode through an exposed second contact electrode and the second reflective electrode.

19. The method of 18, in the sequentially stacking the first and second reflective electrodes and the first and second bottom sacrificial electrodes,
depositing a reflective material layer on the entire surface of the substrate to cover the pixel electrode and the common electrode;
depositing a sacrificial material layer on the entire surface of the substrate to cover all the reflective material layers;
partially etching the sacrificial material layer and the reflective material layer to form the first and second reflective electrodes and the first and second bottom sacrificial electrodes using a first chemical solution that reacts with the first and second reflective electrodes.

20. The method of 18, in the transferring the light emitting elements onto the organic layer so that the first and second contact electrodes of each of the light emitting elements face the pixel electrodes and the common electrodes,
disposing the light emitting elements on the organic layer so that the first and second contact electrodes in each of the light emitting elements face common electrodes with the pixel electrodes, and the transferring the light emitting elements onto the organic layer by heat pressing the light emitting elements,
wherein residual particles of the adhesive layer remain on the organic layer and on the surfaces of the first and second bottom sacrificial electrodes and on the surfaces of the first and second upper sacrificial electrodes by the heat pressing.

21. An electronic device comprising:
a display device; and
a display device driver configured to drive the display device, the display device comprising:
a substrate;
a pixel electrode and a common electrode spaced from each other on the substrate;
a first reflective electrode on the pixel electrode and a second reflective electrode on the common electrode, respectively;
a first bottom sacrificial electrode on the first reflective electrode and a second bottom sacrificial electrode on the second reflective electrode;
an organic layer covering at least a portion of the first and second bottom sacrificial electrodes;
a light emitting element on the organic layer and comprising a semiconductor stack, a first contact electrode and a second contact electrode;
a first connection electrode connecting the pixel electrode and the first contact electrode and a second connection electrode connecting the common electrode and the second contact electrode; and
a first upper sacrificial electrode between the first contact electrode and the organic layer, and a second upper sacrificial electrode between the second contact electrode and the organic layer.

22. The electronic device of claim 21, wherein the electronic device comprises mobile phones, smart phones, tablet personal computers, smart watches, watch phones, mobile communication terminals, electronic notebooks, e-books, portable multimedia players (PMP), navigation, ultra mobile PC (UMPC), televisions, laptops, monitors, billboards, and the internet of things (IoT).
